(19) United States
(12) Patent Application Publication
(10) Pub. No.: US 2006/0187719 A1
(43) Pub. Date: Aug. 24, 2006

(54) Semiconductor package, ID generating system thereof, ID recognizing system thereof, ID recognition method thereof, semiconductor integrated circuit chip, ID generating system thereof, ID recognizing system thereof, and ID recognition method thereof

(75) Inventors: Michikazu Matsumoto, Kyoto (JP); Yasutoshi Okuno, Kyoto (JP); Kazuyoshi Tsukamoto, Osaka (JP); Toshiki Yabu, Osaka (JP)

Correspondence Address: PANASONIC PATENT CENTER;c/o MCDERMOTT WILL & EMERY LLP, 600 13TH STREET, NW, WASHINGTON, DC, 20005-3096, US

(73) Assignee: MATSUSHITA ELECTRIC INDUSTRIAL CO., LTD.

(21) Appl. No.: 11/240,553

(22) Filed: Oct. 3, 2005

(30) Foreign Application Priority Data
Jan. 6, 2005 (JP) 2005-001864

(51) Int. Cl. G11C 7/10

(52) U.S. Cl. 365/189.01

(57) ABSTRACT

In ID generation for a semiconductor package or a semiconductor integrated circuit chip, a topographic characteristic to be utilized as specific information is selected from at least one topographic characteristic that the semiconductor package or the semiconductor integrated circuit has. Then, the selected topographic characteristic is measured as the specific information and an ID for identification is generated for the semiconductor package or the semiconductor integrated circuit chip based on the measured specific information.

### CROSS REFERENCE TO RELATED APPLICATIONS

This Non-provisional application claims priority under 35 U.S.C. § 119(a) on Patent Application No. 2005-001864 filed in Japan on Jan. 6, 2005, the entire contents of which are hereby incorporated by reference.

### BACKGROUND ART

The present invention belongs to the art relating to identification of semiconductor packages or semiconductor integrated circuit chips.

Conventionally, assignment and allocation of specific numbers to semiconductor integrated circuit chips (hereinafter they may be referred to as semiconductor chips merely) have been examined in view of manufacturing process management. Because, in the case where a plurality of semiconductor chips are taken out by dividing a wafer after formation of semiconductor integrated circuits in a wafer state (i.e., diffusion process), it is necessary to acquire, after shipment of the semiconductor chips, information on, for example, when in the diffusion process a certain chip is formed, from which lot it is obtained, from which wafer it is obtained, where in a wafer it is taken out, and so on. Similarly, it is significant to, after packaging semiconductor chips, assign or allocate specific numbers to the packages.

Under the circumstances, conventional techniques for generating a barcode for a semiconductor chip and the like have been utilized (see Japanese Patent Application Laid Open Publication No. 5-13529A, for example). This conventional technique contemplates increasing production efficiency in manufacture in such a manner that a specific ID code is generate in each semiconductor integrated circuit chip region when a stepper exposure is performed in, for example, an aluminum layer patterning process in the diffusion process for semiconductor integrated circuit in a wafer state. Specifically, the aluminum layer is formed also in the periphery (a code region) of each chip region provided in the semiconductor wafer and the aluminum layer in the code region is patterned into a barcode pattern by stepper exposure in patterning the aluminum layer, thereby generating an ID code within the code region of each chip.

Also, as another conventional technique for allocating specific numbers to semiconductor chips, there was proposed a technique in which specific identification information of semiconductor integrated circuit devices is set based on a magnitude relationship in physical quantity of elements to be identified which corresponds to process variation (see International Publication No. 02/45139). In this technique, a flip flop rise pattern formed due to ununiformity in transistor characteristic, which is yield by process variation, is utilized as specific ID information of each chip.

### SUMMARY OF THE INVENTION

As described above, assignment of a specific number to a semiconductor chip itself (or a semiconductor package including a semiconductor chip) is very important in view of the manufacturing process management (to acquire information on when in the diffusion process a semiconductor chip is formed, from which lot it is obtained, from which wafer it is obtained, where in a wafer it is taken out, and so on).

However, artificial assignment of a specific number to a semiconductor chip or the like involves problems of counterfeiting of the specific number and the like in view of information security. As such, for recent application to IC money, IC tags, IC cards, and the like, it becomes much important to add a specific number incapable of being changed from outside to a semiconductor chip itself (or a semiconductor package including a semiconductor chip). In short, provision of an artificially unforgeable semiconductor chip is demanded. Further, in order to attain cost reduction, a method simple as far as possible for adding such a specific number to a semiconductor chip or the like is desired.

In addition, the following is also important. Namely, in the case where a semiconductor chip shipped to the market is judged as a failure (hereinafter referred to as a market failure) upon use, the semiconductor chip is recovered and the specific number (specific number guarded by information security) assigned to the semiconductor chip is recognized again for finding a cause of the failure in a short period of term so as to secure customers' trust on the responsibility of a manufacturing maker.

As described above, in assigning a specific number to a semiconductor chip (or a semiconductor package including a semiconductor chip), it is desired to assign an unforgeable number under protection by information security and to easily extract, upon market failure, the specific number of the failed semiconductor chip for immediately providing countermeasures for customers' benefits.

Referring to the conventional technique for generating a barcode for a semiconductor chip (see Japanese Patent Application Laid Open Publication No. 5-13529A, for example), however, a barcode is assigned to a semiconductor chip artificially, involving problems of counterfeiting and the like in view of information security.

Further, in the other conventional technique for setting a specific ID information to a semiconductor integrated circuit device based on the magnitude relationship in physical quantity of elements to be identified which corresponds to process variation (see International Publication No. 02/45139), the process variation is utilized for setting the specific ID information, so that the specific ID information can be obtained which is not assigned artificially, namely, is under protection by information security. However, as described above, this technique requires an additional step of forming a FF (Flip flop) circuit and causes difficulty in obtaining relatively random specific ID information because the variation in electric characteristic of elements to be identified which corresponds to the process variation is utilized for setting the specific ID information. Further, the electric characteristic of the elements to be identified must be evaluated in setting and extracting the specific ID information, and this raises a possibility of degradation or change of the specific ID information because of degradation in the electric characteristic of the recovered semiconductor chip judged as a market failure in comparison with the one at shipment. At the worst, the semiconductor chip may be electrically defective and the circuit itself may be inoperable when the electric characteristic of the semiconductor chip judged as a market failure is evaluated for acquiring the specific ID information thereof. As a result, the specific ID information of the semiconductor chip cannot be acquired due to inoperability of the semiconductor chip.

In view of the above problems, the present invention has its objects of providing an unforgeable random specific ID information which is under protection by information security in assigning a specific ID information to a semiconductor chip (or a semiconductor package including a semiconductor chip) and of extracting a specific ID information of a failed semiconductor chip or the like for immediately providing countermeasures for customer's benefits in the case of market failure of a semiconductor chip or the like.

To attain the above objects, a semiconductor package ID generating system according to the present invention includes: a function of selecting a topographic characteristic to be utilized as specific information from at least one topographic characteristic that a semiconductor package has; a function of measuring the selected topographic characteristic as the specific information; and a function of generating an ID for identification for the semiconductor package based on the measured specific information.

A semiconductor integrated circuit chip ID generating system according to the present invention includes: a function of selecting a topographic characteristic to be utilized as specific information from at least one topographic characteristic that a semiconductor integrated circuit chip has; a function of measuring the selected topographic characteristic as the specific information; and a function of generating an ID for identification for the semiconductor integrated circuit chip based on the measured specific information.

A semiconductor package ID recognizing system according to the present invention includes: a function of selecting a topographic characteristic to be utilized as specific information from at least one topographic characteristic that a semiconductor package has; a function of measuring the selected topographic characteristic as the specific information; a function of generating an ID for identification for the semiconductor package based on the measured specific information; a function of storing the generated ID for identification into a database; and a function of acquiring again the ID for identification of the semiconductor package by re-measuring the selected topographic characteristic as the specific information and comparing the re-measured specific information with data stored in the database.

A semiconductor integrated circuit chip ID recognizing system according to the present invention includes: a function of selecting a topographic characteristic to be utilized as specific information from at least one topographic characteristic that a semiconductor integrated circuit chip has; a function of measuring the selected topographic characteristic as the specific information; a function of generating an ID for identification for the semiconductor integrated circuit chip based on the measured specific information; a function of storing the generated ID for identification into a database; and a function of acquiring again the ID for identification of the semiconductor integrated circuit by re-measuring the selected topographic characteristic as the specific information and comparing the re-measured specific information with data stored in the database.

A first semiconductor package ID recognition method according to the present invention includes the steps of: selecting a topographic characteristic to be utilized as specific information from at least one topographic characteristic that a semiconductor package has; measuring the selected topographic characteristic as the specific information; generating an ID for identification for the semiconductor package based on the measured specific information; storing the generated ID for identification into a database; and acquiring again the ID for identification of the semiconductor package by re-measuring the selected topographic characteristic as the specific information and comparing the re-measured specific information with data stored in the database.

A first semiconductor integrated circuit chip ID recognition method according to the present invention includes the steps of: selecting a topographic characteristic to be utilized as specific information from at least one topographic characteristic that a semiconductor integrated circuit chip has; measuring the selected topographic characteristic as the specific information; generating an ID for identification for the semiconductor integrated circuit chip based on the measured specific information; storing the generated ID for identification into a database; and acquiring again the ID for identification of the semiconductor integrated circuit chip by re-measuring the selected topographic characteristic as the specific information and comparing the re-measured specific information with data stored in the database.

A semiconductor package according to the present invention includes: a specific information reading region for measuring roughness of a surface of the semiconductor package as specific information for generating an ID for identification, wherein a pattern serving as a starting point for measurement is provided within the specific information reading region.

In the semiconductor package, the surface of the semiconductor package in the specific information reading region may be protected physically.

A second semiconductor package ID recognition method according to the present invention includes the steps of: measuring roughness of a surface of a semiconductor package as specific information; generating an ID for identification for the semiconductor package based on the measured specific information and storing the thus generated ID for identification into a database; and acquiring again the ID for identification of the semiconductor package by re-measuring the roughness as the specific information and comparing the re-measured specific information with data stored in the database.

A third semiconductor package ID recognition method according to the present invention includes the steps of: measuring a lead angle of a bonding wire provided in a semiconductor package as specific information; generating an ID for identification for the semiconductor package based on the measured specific information and storing the thus generated ID for identification into a database; and acquiring again the ID for identification of the semiconductor package by re-measuring the lead angle as the specific information and comparing the re-measured specific information with data stored in the database.

A fourth semiconductor package ID recognition method according to the present invention includes the steps of: measuring a contour of a bonding portion provided in a semiconductor package as specific information; generating an ID for identification for the semiconductor package based on the measured specific information and storing the thus generated ID for identification into a database; and acquiring again the ID for identification of the semiconductor package by re-measuring the contour of the bonding portion as the specific information and comparing the re-measured specific information with data stored in the database.

A fifth semiconductor package ID recognition method according to the present invention includes the steps of: measuring a shape of a bump provided in a semiconductor package as specific information; generating an ID for identification for the semiconductor package based on the measured specific information and storing the thus generated ID for identification into a database; and acquiring again the ID for identification of the semiconductor package by re-measuring the shape of the bump as the specific information and comparing the re-measured specific information with data stored in the database.

A first semiconductor integrated circuit chip according to the present invention includes: a specific information reading region provided on an obverse face, a side face, or a reverse face for measuring a topographic characteristic of a constitutional element of the semiconductor integrated circuit chip as specific information for generating an ID for identification.

In the first semiconductor integrated circuit chip, it is possible that the constitutional element is a metal film, the topographic characteristic is an aspect of a grain boundary of the metal film, and at least a part of the metal film is exposed in the specific information reading region.

In the first semiconductor integrated circuit chip, it is possible that the constitutional element is a wire, the topographic characteristic is an edge outline of the wire, and at least a part of the wire is exposed in the specific information reading region.

In the first semiconductor integrated circuit chip, the specific information reading region may be provided in a region other than a region where a bonding pad to which a bonding wire is connected is formed.

In the first semiconductor integrated circuit chip, the metal film may be made of copper, aluminum, tungsten, or an alloy thereof.

A second semiconductor integrated circuit chip ID recognition method according to the present invention includes: a first step of measuring an aspect of grain boundaries of a metal film provided in a semiconductor integrated circuit chip as specific information; a second step of generating an ID for identification for the semiconductor integrated circuit chip based on the measured specific information and storing the generated ID for identification into a database; and a third step of acquiring again the ID for identification of the semiconductor integrated circuit chip by re-measuring the aspect of the grain boundaries as the specific information and comparing the re-measured specific information with data stored in the database.

In the second semiconductor integrated circuit chip ID recognition method, it is possible that the first step includes a step of extracting, after an image of the grain of the metal film is obtained, the aspect of the grain boundaries of the metal film by subjecting the image to image processing and the second step includes a step of extracting a point that connects the grain boundaries with each other, which are extracted in the first step, and storing a position of the extracted point as the ID for identification into the database.

A third semiconductor integrated circuit chip ID recognition method according to the present invention includes the steps of: measuring an edge outline of a wire provided in a semiconductor integrated circuit chip as specific information; generating an ID for identification for the semiconductor integrated circuit chip based on the measured specific information and storing the generated ID for identification into a database; and acquiring again the ID for identification of the semiconductor integrated circuit chip by re-measuring the edge outline as the specific information and comparing the re-measured specific information with data stored in the database.

A fourth semiconductor integrated circuit chip ID recognition method according to the present invention includes the steps of: measuring, as specific information, a profile of roughness or chapping generated in a side surface portion of a semiconductor integrated circuit chip in chip dicing; generating an ID for identification for the semiconductor integrated circuit chip based on the measured specific information and storing the generated ID for identification into a database; and acquiring again the ID for identification of the semiconductor integrated circuit chip by re-measuring the profile of the roughness or the chapping as the specific information and comparing the re-measured specific information with data stored in the database.

A second semiconductor integrated circuit chip according to the present invention includes: a specific information reading region on a reverse face thereof for measuring an aspect of the reverse face as specific information for generating an ID for identification, wherein a pattern serving as a starting point for measurement is provided within the specific information reading region.

A fifth semiconductor integrated circuit chip ID recognition method according to the present invention includes the steps of: measuring an aspect of a reverse face of a semiconductor integrated circuit chip as specific information; generating an ID for identification for the semiconductor integrated circuit chip based on the measured specific information and storing the generated ID for identification into a database; and acquiring again the ID for identification of the semiconductor integrated circuit chip by re-measuring the aspect of the reverse face as the specific information and comparing the re-measured specific information with data stored in the database.

According to the present invention, the topographic characteristic that a semiconductor package or a semiconductor chip (hereinafter they may be referred to as “chip or the like”) has is utilized as specific information of the chip or the like, acquiring physically random specific information. Accordingly, an unforgeable ID (hereinafter it may be referred to as “chip ID or the like”) for identification which exhibits a very strict information security function can be assigned to a chip or the like based on the specific information. Further, for satisfying a demand for speedy countermeasures for customers' benefits upon market failure of a semiconductor chip, a cause of the failure can be found in an early stage by re-extracting the chip ID or the like by measuring again the physically random specific information that the chip or the like has. In addition, a topographic characteristic serving as physically random specific information is utilized as the chip ID or the like, so that the chip ID or the like of a chip or the like electrically inoperable due to market failure can be re-extracted independently from the electric circuit operation of the chip or the like. Thus, the effects of the present invention are significant.

As described above, when the present invention is utilized for identifying a semiconductor package or a semiconductor integrated circuit chip, an unforgeable ID for identification which exhibits a very strict information security function can be provided, offering useful effects.

### BRIEF DESCRIPTION OF THE DRAWINGS

FIG. 1 is a diagram showing one example of a schematic constitution of a semiconductor package ID generating system according to Embodiment 1 of the present invention.

FIG. 2 is a flowchart of a semiconductor package ID generation method according to Embodiment 1 of the present invention.

FIG. 3 is a diagram showing one example of a schematic constitution of a semiconductor integrated circuit chip ID generating system according to Embodiment 2 of the present invention.

FIG. 4 is a flowchart of a semiconductor integrated circuit chip ID generation method according to Embodiment 2 of the present invention.

FIG. 5 is a flowchart of a semiconductor package ID recognition method according to Embodiment 3 of the present invention.

FIG. 6 is a flowchart of a semiconductor integrated circuit chip ID recognition method according to Embodiment 4 of the present invention.

FIG. 7A to FIG. 7D are diagrams for explaining a semiconductor package according to Embodiment 5 of the present invention.

FIG. 8A and FIG. 8B are diagrams for explaining a semiconductor package according to Embodiment 6 of the present invention.

FIG. 9A to FIG. 9E are diagrams for explaining a semiconductor package ID recognition method according to Embodiment 7 of the present invention.

FIG. 10 is a flowchart of a semiconductor package ID recognition method according to Embodiment 7 of the present invention.

FIG. 11A and FIG. 11B are diagrams for explaining a semiconductor package ID recognition method according to Embodiment 8 of the present invention.

FIG. 12 is drawing showing one example of an X-ray photograph of bonding wires obtained in the semiconductor package ID recognition method according to Embodiment 8 of the present invention.

FIG. 13A and FIG. 13B are diagrams for explaining a semiconductor package ID recognition method according to Embodiment 9 of the present invention.

FIG. 14A to FIG. 14D are diagrams for explaining a semiconductor package ID recognition method according to Embodiment 10 of the present invention.

FIG. 15A to FIG. 15C are perspective views showing a variety of semiconductor integrated circuit chips according to Embodiment 11 of the present invention.

FIG. 16A and FIG. 16B are a sectional view and a plan view, respectively, of a semiconductor integrated circuit chip according to Embodiment 12 of the present invention.

FIG. 17A is a sectional view of a semiconductor integrated circuit chip according to Embodiment 13 of the present invention and FIG. 17B is a plan view in an enlarged scale of wires exposed in a specific information reading region of the semiconductor integrated circuit chip according to Embodiment 13 of the present invention.

FIG. 18A to FIG. 18E are drawings for explaining a semiconductor integrated circuit chip ID recognition method according to Embodiment 14 of the present invention.

FIG. 19A to FIG. 19C are diagrams for explaining a semiconductor integrated circuit chip ID recognition method according to Embodiment 15 of the present invention.

FIG. 20A to FIG. 20C are diagrams for explaining a semiconductor integrated circuit chip ID recognition method according to Embodiment 16 of the present invention.

FIG. 21A to FIG. 21C are diagrams for explaining a semiconductor integrated circuit chip according to Embodiment 17 of the present invention.

FIG. 22A and FIG. 22B are diagrams for explaining a semiconductor integrated circuit chip ID recognition method according to Embodiment 18 of the present invention.

### DETAILED DESCRIPTION OF THE INVENTION

### Embodiment 1

A semiconductor package ID generating system according to Embodiment 1 of the present invention will be described below with reference to the drawings.

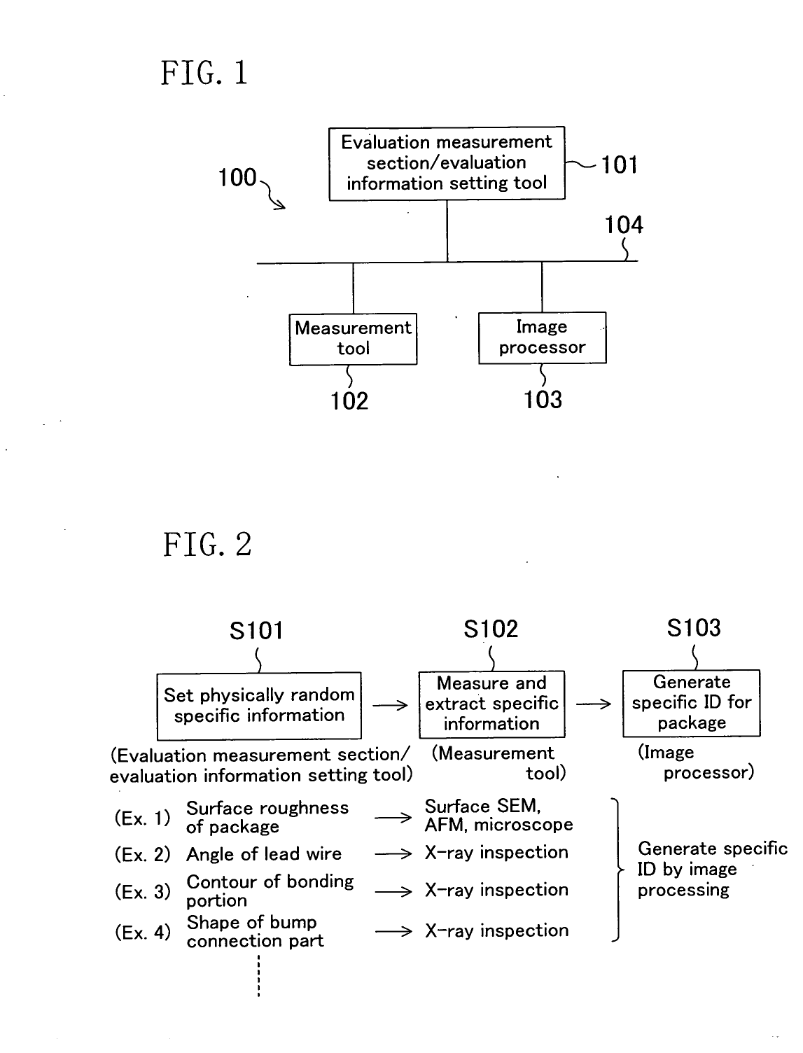

FIG. 1 is a diagram showing one example of a schematic constitution of a semiconductor package ID generating system according to Embodiment 1. As shown in FIG. 1, an ID generating system 100 of the present embodiment includes: an evaluation measurement section/evaluation information setting tool 101 which selects a topographic characteristic utilized as specific information from a plurality of topographic characteristics that a semiconductor package (specifically, a semiconductor package including a semiconductor integrated circuit chip) has and which specifies a measurement point of the selected topographic characteristic (i.e., the specific information) in the semiconductor package; a measurement tool 102 used for measuring and extracting the specific information; and a specific ID generating tool (an image processor in the present embodiment) 103 that generates an ID for identification (hereinafter referred to as a package ID) for a semiconductor package by processing the measured specific information for identification. The evaluation measurement section/evaluation information setting tool 101 is composed of, for example, a main control section (CPU: central processing unit) and a memory device. The CPU executes the aforementioned functions upon an instruction of a program in a memory and performs input and output of necessary data to and from the memory device. It is noted that the evaluation measurement section/evaluation information setting tool 101 may have, in addition to the aforementioned functions, a function of determining the measurement tool 102 to be used according to the kind of the selected topographic characteristic, that is, the type of the specific information. The evaluation measurement section/evaluation information setting tool 101, the measurement tool 102, and the image processor 103 are connected with one another through a network 104.

The most significant feature of the present embodiment lies in that a topographic characteristic that a semiconductor package has is set as the specific information, so that the specific information becomes distinctive and physically random.

A method for identifying a semiconductor package by the ID generating system of the present embodiment will be described below. FIG. 2 shows a flow of the ID generation method in the present embodiment.

In the present embodiment, in a step S101 first, a topographic characteristic of a semiconductor package to be utilized as the physically random specific information is selected and a measurement point of the thus selected topographic characteristic (i.e., the specific information) is set, using the evaluation measurement section/evaluation information setting tool 101. The topographic characteristic of a semiconductor package herein means, for example, roughness that the surface of the package forms (in general, a plastic resin with which a silicon filler is mixed is used as a resin for packaging, forming roughness in the surface portion of a package), an angle of a lead wire (a bonding wire) connected to a semiconductor chip in a package, a contour of a bonding portion where a lead wire is connected to a bonding pad of a semiconductor chip, a shape of a bump (a bump connection part) used in lieu to a lead wire, and the like, and is not limited specifically only if it can be utilized as the physically random specific information.

Next, in a step S102, the topographic characteristic selected in the step S101, that is, the physically random specific information of the semiconductor package is measured and extracted using the measurement tool 102. For observing, for example, roughness that the surface of the package forms, a surface SEM (a surface scanning electron microscope), an AFM (an atomic force microscope), a microscope, and the like can be used as the measurement tool 102 in the present embodiment. Alternatively, for observing the angle of a lead wire, the contour of a bonding portion, and the shape of a bump, a measurement tool capable of radioscopic observation using the X-ray may be used.

Finally, in a step S103, the information (data) measured and extracted in the step S102 is processed for identification using the image processor (specific ID generating tool) 103, thereby generating a specific ID (package ID) for the target semiconductor package. Specifically, the image processor 103 performs image processing of the data (for example, an image of a photo or the like obtained through observation by a surface SEM) measured by the measurement tool 102 and relating to the physically random specific information to allow the thus processed data to be used as a package ID. In this way, the specific ID generation for the semiconductor package is performed.

In a case employing image processing for the specific ID generation for the semiconductor package, a significant effect of data compaction (contraction) can be attained. With this effect, even in a case with a huge number of semiconductor packages to be evaluated, specific IDs can be generated for the semiconductor packages efficiently.

Further, the package ID obtained as above is stored in, for example, a memory device of a computer together with manufacture information on the semiconductor package (a manufacturing factory, a manufacturing line, manufacturing date, a lot number, a wafer number, and a chip number).

As described above, in the present embodiment, a topographic characteristic that a semiconductor package has is utilized as the specific information, acquiring the physically random specific information. Accordingly, an unforgeable package ID exhibiting a high-level information security function can be assigned to a semiconductor package based on the specific information. For immediately providing countermeasures for customers' benefits upon market failure of a semiconductor package, the package ID is re-extracted by measuring again the physically random specific information that the semiconductor package has, enabling speedy failure cause finding. In addition, the package ID of the present embodiment is set based on a topographic characteristic, so that the package ID of a semiconductor package electrically inoperable due to market failure can be re-extracted independently from the electric circuit operation of the semiconductor package. Thus, the effects of the present invention are significant.

Needless to say, in the present embodiment, the physically random specific information measured and extracted by the measurement tool 102 may be used directly as the package ID. It is also needless to say that any method other than the image processing may be employed as the ID generation method of the specific information.

### Embodiment 2

A semiconductor integrated circuit chip ID generating system according to Embodiment 2 of the present invention will be described below with reference to the drawings.

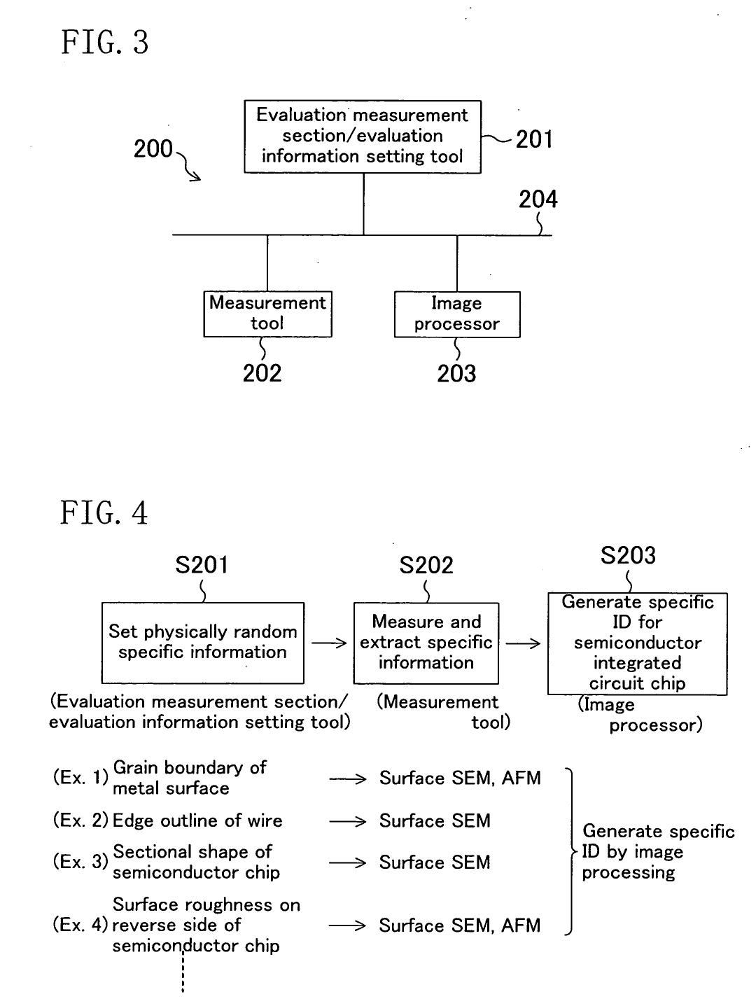

FIG. 3 is a diagram showing one example of a schematic constitution of the semiconductor integrated circuit chip ID generating system according to Embodiment 2. As shown in FIG. 3, an ID generating system 200 of the present embodiment includes: an evaluation measurement section/evaluation information setting tool 201 which selects a topographic characteristic utilized as specific information from a plurality of topographic characteristics that a semiconductor integrated circuit chip has and which specifies a measurement point of the thus selected topographic characteristic (i.e., the specific information) in the semiconductor chip; a measurement tool 201 used for measuring and extracting the specific information; and a specific ID generating tool (an image processor in the present embodiment) 203 that generates a chip ID by processing the thus measured specific information for identification. The evaluation measurement section/evaluation information setting tool 201 is composed of, for example, a main control section (CPU) and a memory device. The CPU executes the aforementioned functions upon an instruction of a program in a memory and performs input and output of necessary data to and from the memory device. It is noted that the evaluation measurement section/evaluation information setting tool 201 may have, in addition to the aforementioned functions, a function of determining the measurement tool 202 to be used according to the kind of the selected topographic characteristic, that is, the type of the specific information. The evaluation measurement section/evaluation information setting tool 201, the measurement tool 202, and the image processor 203 are connected with one another through a network 204.

The most significant feature of the present embodiment lies in that a topographic characteristic that a semiconductor integrated circuit chip has is set as the specific information, so that the specific information becomes distinctive and physically random.

A method for generating an ID for a semiconductor integrated circuit chip by the ID generating system of the present embodiment will be described below. FIG. 4 shows a flow of the ID generation method in the present embodiment.

In the present embodiment, in a step S201 first, a topographic characteristic of a semiconductor integrated circuit chip to be utilized as physically random specific information is selected and a measurement point of the thus selected topographic characteristic (i.e., the specific information) is set, using the evaluation measurement section/evaluation information setting tool 201. The topographic characteristic of a semiconductor integrated circuit chip herein means, for example, a grain boundary of the surface of a metal layer, an edge outline of a metal wire, a sectional shape of a divided semiconductor integrated circuit chip, surface roughness on the reverse side of a semiconductor integrated circuit chip, and the like and is not limited specifically only if it can be utilized as the physically random specific information.

Next, in a step S202, the topographic characteristic selected in the step S201, that is, the physically random specific information of the semiconductor integrated circuit chip is measured and extracted using the measurement tool 202. For observing a grain boundary of the surface of a metal layer or surface roughness on the reverse side of a semiconductor integrated circuit chip, a surface SEM or an AFM can be used as the measurement tool 202 in the present embodiment. Alternatively, for observing an edge outline of a metal wire or a sectional shape of a divided semiconductor integrated circuit chip, a surface SEM can be used, for example.

Finally, in a step S203, an ID is generated from the information (data) measured and extracted in the step S202 using the image processor (a specific ID generating tool) 203, thereby generating a specific ID (chip ID) for the target semiconductor integrated circuit chip. Specifically, the image processor 203 performs image processing of the data (for example, an image of a photo or the like obtained through observation by a surface SEM) measured by the measurement tool 102 and relating to the physically random specific information to allow the thus processed data to be used as a chip ID. In this way, the specific ID generation for the semiconductor integrated circuit chip is performed.

In a case employing image processing for the specific ID generation for the semiconductor integrated circuit chip, a significant effect of data compaction (contraction) can be attained. With this effect, even in a case with a huge number of semiconductor integrated circuit chips to be evaluated, specific ID chips can be generated for the semiconductor integrated circuit efficiently.

Further, the chip ID obtained as above is stored in, for example, a memory device of a computer together with manufacture information on the semiconductor integrated circuit chip (a manufacturing factory, a manufacturing line, manufacturing date, a lot number, a wafer number, and a chip number).

As described above, in the present embodiment, a topographic characteristic that a semiconductor integrated circuit chip has is utilized as the specific information, attaining the physically random specific information. Accordingly, an unforgeable chip ID exhibiting a high-level information security function can be assigned to a semiconductor integrated circuit chip based on the specific information. For immediately providing countermeasures for customers' benefits upon market failure of a semiconductor integrated circuit, the chip ID is re-extracted by measuring again the physically random specific information that the semiconductor integrated circuit chip has, enabling speedy failure cause finding. In addition, the chip ID of the present embodiment is set based on a topographic characteristic of a semiconductor integrated circuit chip, so that the chip ID of a semiconductor integrated circuit chip electrically inoperable due to market failure can be re-extracted independently from the electric circuit operation of the semiconductor integrated circuit chip. Thus, the effects of the present invention are significant.

Needless to say, in the present embodiment, the physically random specific information measured and extracted by the measurement tool 202 may be used directly as the chip ID. Also, it is needless to say that any method other than the image processing may be employed as the ID generation method from the specific information.

### Embodiment 3

A semiconductor package ID recognition method and a semiconductor package ID recognizing system according to Embodiment 3 of the present invention will be described below with reference to the drawing.

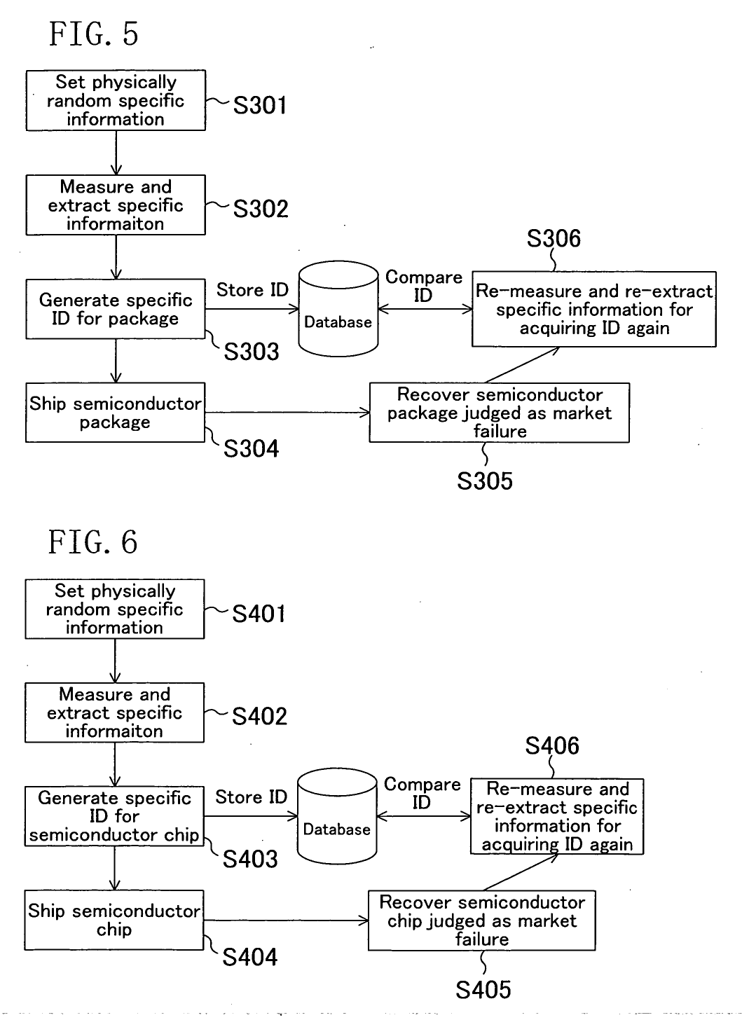

FIG. 5 shows a flow of the ID recognition method of a semiconductor package (specifically, a semiconductor package including a semiconductor integrated circuit) according to Embodiment 3.

In the present embodiment, in a step S301 first, a topographic characteristic of a semiconductor package to be utilized as physically random specific information is selected and a measurement point of the thus selected topographic characteristic (i.e., the specific information) is set. The topographic characteristic of a semiconductor package herein means, for example, roughness that the surface of a package forms (in general, a plastic resin with which a silicon filler is mixed is used as a resin for packaging, forming roughness in the surface portion of a package), an angle of a lead wire (a bonding wire) connected to a semiconductor chip in a package, a contour of a bonding portion where a lead wire is connected to a bonding pad of a semiconductor chip, a shape of a bump (a bump connection part) used in lieu to a lead wire, and the like, and is not limited specifically only if it can be utilized as the physically random specific information.

Next, in a step S302, the topographic characteristic selected in the step S301, that is, the physically random specific information of the semiconductor package is measured and extracted. Herein, for observing surface roughness that a package forms, a surface SEM, an AFM, a microscope, or the like can be used as a tool for measuring the physically random specific information. Alternatively, for observing a lead wire angle, a contour of a bonding portion, or a shape of a bump, a measurement tool capable of radioscopic observation using the X-ray may be used.

Subsequently, in a step S303, the information (data) measured and extracted in the step S302 is processed for identification using, for example, an image processor, thereby generating a specific ID (package ID) for the target semiconductor package. Specifically, the image processor performs image processing of the data measured by the aforementioned measurement tool and relating to the physically random specific information (for example, an image of a photo or the like obtained through observation by a surface SEM) to allow the thus processed data to be used as a package ID. In this way, the specific ID generation for the semiconductor package is performed.

In a case employing image processing for the specific ID generation for the semiconductor package, a significant effect of data compaction (contraction) can be attained. With this effect, even in the case of a huge number of semiconductor packages to be evaluated, specific ID can be generated for the semiconductor packages efficiently.

Further, the package ID obtained as above is stored in, for example, a memory device of a computer together with manufacture information on the semiconductor package (a manufacturing factory, a manufacturing line, manufacturing date, a lot number, a wafer number, and a chip number).

Thereafter, in a step S304, the semiconductor package for which the package ID is set is shipped to the market as a product to be used in general electric equipment.

In conventional semiconductor packages, the product number, the name of the manufacturing maker, and the like are imprinted usually in the surface portion of the package. No problem is involved when the product number, the name of the manufacturing maker, and the like are imprinted in the surface portion of the semiconductor package of the present embodiment in which the physically random specific information is set as the package ID. In this case, the use of the physically random specific information as the package ID in addition to such imprint is the feature of the semiconductor package. In the present embodiment, of course, only the physically random specific information may be used as the package ID without the imprint in the surface portion of the package. In detail, imprint of the product number, the manufacturing maker and the like in the surface portions of the conventional semiconductor packages is forged easily, resulting in being of no use for preventing semiconductor packages including semiconductor integrated circuit chips from being forged. In contrast, the package ID of the present invention, which utilizes the physically random specific information, prevents forging of the semiconductor package reliably.

Next, in the case where a semiconductor package shipped to the market as a product is judged as a market failure, the failed semiconductor package is recovered in a step S305 for investigating the manufacture history thereof.

Then in a step S306, the topographic characteristic selected in the step S301, that is, the physically random specific information of the recovered semiconductor package judged as a market failure is measured and extracted again. Then, the thus measured and extracted physically random specific information is compared with the package ID that has been stored in the database prior to the product shipment so that the package ID of the semiconductor package is acquired again. Thus, the package ID of the recovered semiconductor package judged as a market failure can be recognized again, so that easy investigation of the manufacture history and the like of the semiconductor package is enabled, resulting in speedy failure cause finding.

As described above, in the present embodiment, the topographic characteristic that the semiconductor package has is utilized as the specific information, so that the specific information becomes distinctive and physically random. In consequence, an unforgeable package ID exhibiting a high-level information security function can be assigned to a semiconductor package. Further, for immediately providing countermeasures for customers' benefits upon market failure of a semiconductor package, the package ID is re-extracted by measuring again the physically random specific information that the semiconductor package has, enabling speedy failure cause finding. In addition, the package ID of the present embodiment is set based on a topographic characteristic, so that the package ID of a semiconductor package electrically inoperable due to market failure can be re-extracted independently from the electric circuit operation of the semiconductor package. Thus, the effects of the present invention are significant.

Referring to an ID recognizing system for performing the semiconductor package ID recognition method according to the present embodiment may be composed by adding, to the semiconductor package ID generating system according to embodiment 1 shown in FIG. 1, a function of storing the package ID into a database and a function of acquiring again the package ID of the semiconductor package by, for example, comparing the specific information re-measured by the measurement tool 102 of Embodiment 1 with the contents stored in the database. Herein, both the functions can be realized by a combination of the CPU and the memory device, similar to the evaluation measurement section/evaluation information setting tool 101 in Embodiment 1. In detail, the CPU executes both the functions upon an instruction of a program in a memory and performs input and output of necessary data to and from the memory device.

Needless to say, in the present embodiment, the physically random specific information measured and extracted by the measurement tool may be used directly as the package ID. Also, it is needless to say that any method other than the image processing may be employed as the specific ID generation method.

### Embodiment 4

A semiconductor integrated circuit chip ID recognition method and a semiconductor integrated circuit chip ID recognizing system according to Embodiment 4 of the present invention will be described below with reference to the drawing.

FIG. 6 shows a flow of the semiconductor integrated circuit chip ID recognition method according to Embodiment 4.

In the present embodiment, in a step S401 first, a topographic characteristic of a semiconductor integrated circuit chip to be utilized as physically random specific information is selected and a measurement point of the thus selected topographic characteristic (i.e., the specific information) is set. The topographic characteristic of a semiconductor integrated circuit chip herein means, for example, a grain boundary of the surface of a metal layer, an edge outline of a metal wire, a sectional shape of a divided semiconductor integrated circuit chip, surface roughness on the reverse side of a semiconductor integrated circuit chip, and the like and is not limited specifically only if it can be utilized as the physically random specific information.

Next, in a step S402, the topographic characteristic selected in the step S401, that is, the physically random specific information of the semiconductor integrated circuit chip is measured and extracted. For observing a grain boundary of the surface of a metal layer or surface roughness on the reverse side of a semiconductor integrated circuit chip, for example, a surface SEM or an AFM can be used as the measurement tool in the present embodiment. Alternatively, for observing an edge outline of a metal wire or a sectional shape of a divided semiconductor integrated circuit chip, a surface SEM can be used, for example.

Subsequently, in a step S403, the information (data) measured and extracted in the step S302 is processed for identification using, for example, an image processor, thereby generating a specific ID (chip ID) for the target semiconductor integrated circuit. Specifically, the image processor performs image processing of the data measured by the aforementioned measurement tool and relating to the physically random specific information (for example, an image of a photo or the like obtained through observation by a surface SEM) to allow the thus processed data to be used as a chip ID. In this way, the specific ID generation for the semiconductor integrated circuit chip is performed.

In a case employing image processing for the specific ID generation for the semiconductor integrated circuit chip, a significant effect of data compaction (contraction) can be attained. With this effect, even in a case with a huge number of semiconductor integrated circuit chips to be evaluated, specific ID can be generated for the semiconductor integrated circuit chips efficiently.

Further, the chip ID obtained as above is stored in, for example, a database provided in a memory device of a computer together with manufacture information on the semiconductor integrated circuit chip (a manufacturing factory, a manufacturing line, manufacturing date, a lot number, a wafer number, and a chip number).

Thereafter, in a step S404, the semiconductor integrated circuit chip for which the chip ID is set is shipped to the market as a product to be used in general electric equipment.

In conventional semiconductor integrated circuit chips, the numbers capable of discriminating chips, for example, the product number and the like are not set for each chip. Although a method of setting a barcode to a semiconductor integrated circuit chip has been employed conventionally (see Japanese Patent Application Laid Open Publication No. 5-13529A, for example), such an artificially set number is not useful at all for preventing a semiconductor integrated circuit chip from being forged. In contrast, the chip ID using the physically random specific information in the present embodiment can prevent reliably the semiconductor integrated circuit chip form being forged.

Next, in the case where a semiconductor integrated circuit chip shipped to the market as a product is judged as a market failure, the failed semiconductor package is recovered in a step S405 for investigating the manufacture history thereof.

Then in a step S406, the topographic characteristic selected in the step S401, that is, the physically random specific information of the recovered semiconductor integrated circuit chip judged as a market failure is measured and extracted again. Then, the thus measured and extracted physically random specific information is compared with the chip ID that has been stored in the database prior to the product shipment so that the chip ID of the semiconductor integrated circuit chip is acquired again. Thus, the chip ID of the recovered semiconductor integrated circuit chip judged as a market failure can be recognized again, so that easy investigation of the manufacture history and the like of the semiconductor integrated circuit chip is enabled, resulting in speedy failure cause finding.

As described above, in the present embodiment, the topographic characteristic that the semiconductor integrated circuit chip has is utilized as the specific information, so that the specific information becomes distinctive and physically random. In consequence, an unforgeable chip ID exhibiting a high-level information security function can be assigned to a semiconductor integrated circuit chip. Further, for immediately providing countermeasures for customers' benefits upon market failure of a semiconductor integrated circuit chip, the chip ID is re-extracted by measuring again the physically random specific information that the semiconductor integrated circuit chip has, enabling speedy failure cause finding. In addition, the chip ID of the present embodiment is set based on a topographic characteristic, so that the chip ID of a semiconductor integrated circuit chip electrically inoperable due to market failure can be re-extracted independently from the electric circuit operation of the semiconductor integrated circuit chip. Thus, the effects of the present invention are significant.

Referring to an ID recognizing system for performing the semiconductor integrated circuit chip ID recognition method according to the present embodiment may be composed by adding, to the semiconductor integrated circuit chip ID generating system according to embodiment 2 shown in FIG. 3, a function of storing the chip ID into a database and a function of acquiring again the chip ID of the semiconductor integrated circuit chip by, for example, comparing the specific information re-measured by the measurement tool 202 of Embodiment 2 with the contents stored in the database. Herein, both the functions can be realized by a combination of the CPU and the memory device, similar to the evaluation measurement section/evaluation information setting tool 201 in Embodiment 2. In detail, the CPU executes both the functions upon an instruction of a program in a memory and performs input and output of necessary data to and from the memory device.

Needless to say, in the present embodiment, the physically random specific information measured and extracted by the measurement tool may be used directly as the chip ID. It is also needless to say that any method other than the image processing may be employed as the specific ID generation method.

### Embodiment 5

A semiconductor package according to Embodiment 5 of the present invention will be described below with reference to the drawings.

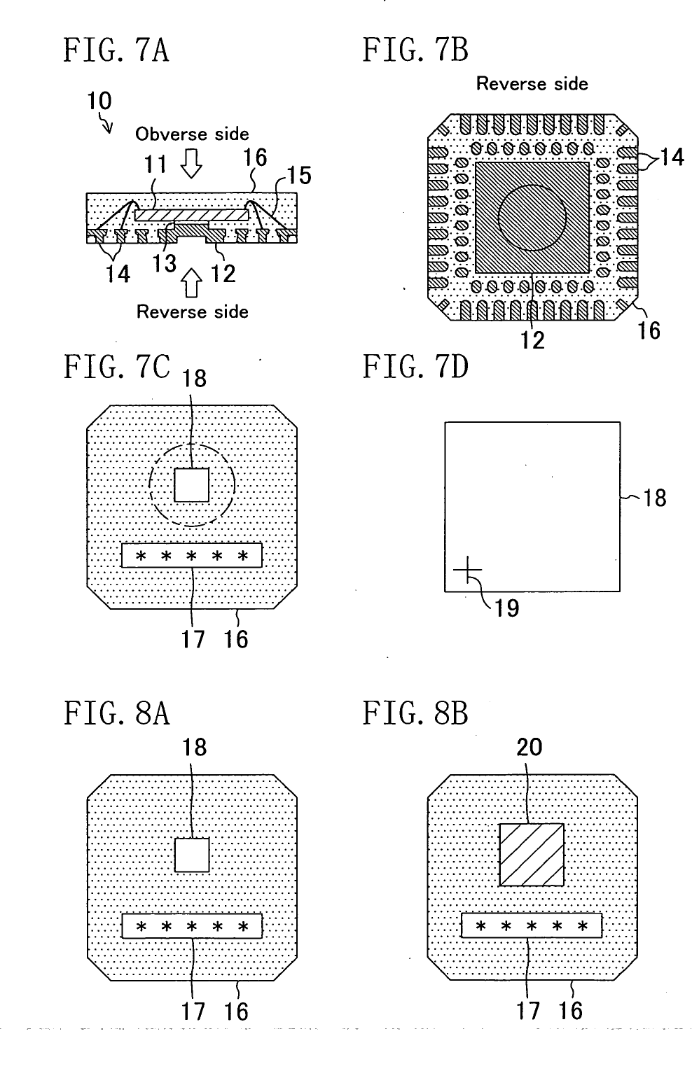

FIG. 7A shows one example of a construction in section of the semiconductor package (a semiconductor package including a semiconductor integrated circuit chip) according Embodiment 5. As recent techniques for semiconductor packaging, there are SEP (System Embedded Packaging) in which a plurality of semiconductor chips are layered and packaged, CSP (Chip Size Packaging) capable of packaging in a small chip size area. Wherein, a semiconductor package 10 shown in FIG. 7A in the present embodiment is packaged by Lead Frame CSP, which is one of CSP techniques. In the present embodiment, Lead Frame CSP is explained as an example, but semiconductor packages employing any other package techniques are, of course, applicable to the present invention.

As shown in FIG. 7A, a semiconductor chip 11 is mounted on a die pad portion 12 of a lead frame with an adhesive layer 13 interposed. The semiconductor chip 11 and an external terminal portion 14 of the lead frame are connected electrically by means of a bonding wire (lead wire) 15. The semiconductor chip 11, the die pad portion 12, the adhesive layer 13, the external terminal portion 14, and the bonding wire (lead wire) 15 are covered with a resin package 16.

FIG. 7B shows an aspect of the semiconductor package shown in FIG. 7A in the present embodiment as viewed from the reverse side thereof. As shown in FIG. 7B, the external terminal portion 14 is exposed at the reverse face of the package so as to be connected to electrical equipment. Wherein, the semiconductor chip (semiconductor integrated circuit chip) 11 is entirely covered with a resin in the Lead Frame CSP in the present embodiment. A plastic resin with which a silicon filler is mixed for ensuring the strength and the like is used as the resin in general.

FIG. 7C shows another aspect of the semiconductor package shown in FIG. 7A in the present embodiment as viewed from the obverse side. As shown in FIG. 7C, an imprint portion 17 where the product number, the manufacturing maker, and the like are imprinted is provided on the surface of the semiconductor package. The most significant feature of the present embodiment lies in that a specific information reading region 18 for reading the surface roughness of the package as the physically random specific information (to be used for generating a package ID) is provided on the surface of the semiconductor package in addition to the imprint portion 17 for the product number and the like. Herein, the surface roughness of the resin package 16 is physically random roughness generated due to the existence of the silicon filler contained in the plastic resin forming the resin package 16.

FIG. 7D is a view in an enraged scale of a region (specific information reading region 18) encircled by the dash-dot line in FIG. 7C. As shown in FIG. 7D, a starting point pattern 19 is provided within the specific information reading region 18 so as to clearly indicate a starting point for measurement of the surface roughness of the package.

In the present embodiment, the surface roughness of the package is measured and evaluated by, for example, SEM observation using the starting point pattern 19 as, for example, an origin of the X-Y axes, so that specific information of the semiconductor packages different from one another can be acquired. Thus, an unforgeable package ID exhibiting a high-level information security function can be assigned to a semiconductor package based on the specific information. For immediately providing countermeasures for customers' benefits upon market failure of a semiconductor package, the package ID is re-extracted by measuring again the physically random specific information that the semiconductor package has, enabling speedy failure cause finding. In addition, the package ID of the present embodiment is set based on a topographic characteristic, so that the package ID of a semiconductor package electrically inoperable due to market failure can be re-extracted independently from the electric circuit operation of the semiconductor package. Thus, the effects of the present invention are significant.

### Embodiment 6

A semiconductor package according to Embodiment 6 of the present invention will be described below with reference to the drawings.

A difference of the present embodiment from Embodiment 5 is that the surface of a package in the specific information reading region 18 is covered with a protection film 20.

FIG. 8A shows an aspect of the semiconductor package according to Embodiment 5 as viewed from the obverse side, and FIG. 8B shows an aspect of the semiconductor package according to the present embodiment as viewed from the obverse side. Wherein, in FIG. 8A and FIG. 8B, the same reference numerals are assigned to the same constitutional elements as those in the semiconductor package shown in FIG. 7A to FIG. 7D according to Embodiment 5. As shown in FIG. 8A and FIG. 8B, the surface of the package in the specific information reading region 18 is covered with the protection film 20, different from the case in Embodiment 5.

According to the present embodiment, the following effects can be obtained in addition to the effects obtained in Embodiment 5. Namely, the protection film 20 prevents the surface of the package in the specific information reading region 18 from being contaminated by human touch after the semiconductor package appears on the market.

It is noted that the protection film 20 may be formed of plastic or the like in the present embodiment but a material other than plastic may be used as the material of the protection film 20 only if the surface of the package in the specific information reading region 18 is out of contact from outside through such a material.

### Embodiment 7

A semiconductor package ID recognition method according to Embodiment 7 of the present invention will be descried below with reference to the drawings.

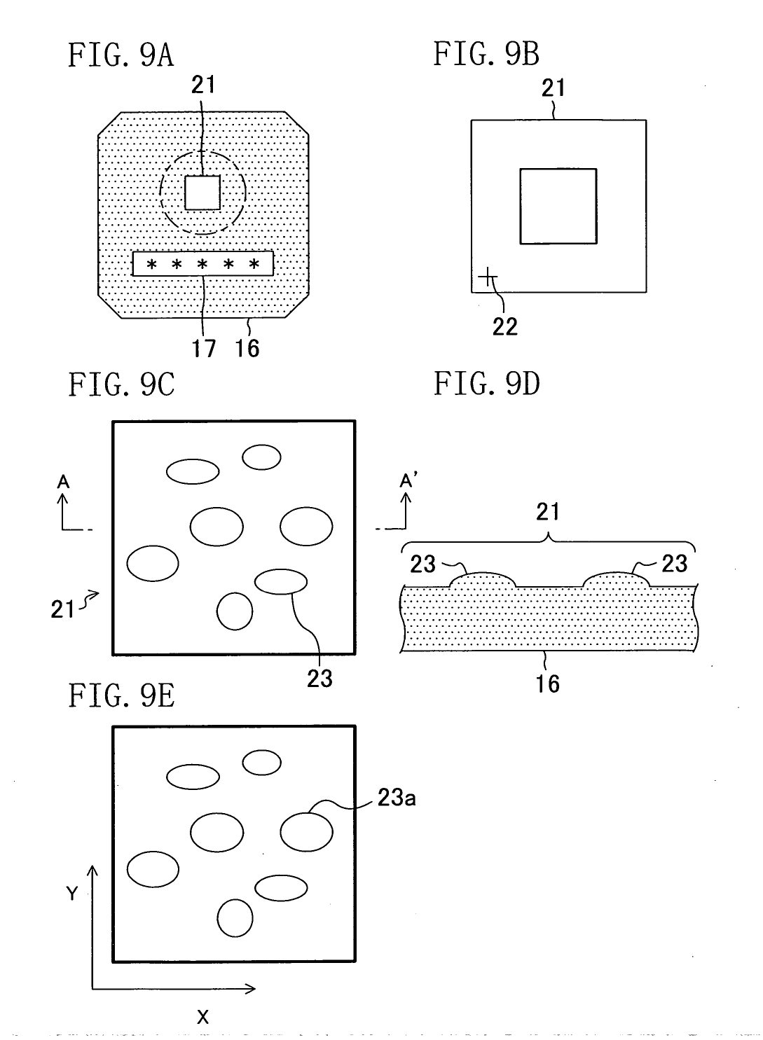

FIG. 9A shows an aspect of a semiconductor package used in the present embodiment as viewed from the obverse side. Wherein, the semiconductor package used in the present embodiment is basically the same as the semiconductor package according to Embodiment 5 and the same reference numerals are assigned to the same constitutional elements as those in the semiconductor package shown in FIG. 7A to FIG. 7D according to Embodiment 5. As shown in FIG. 9A, there are provided on the surface of the semiconductor package an imprint portion 17 where the product number, the manufacturing maker, and the like are imprinted and a specific information reading region 21 from which the surface roughness of the package is read as the physically random specific information (to be used for generating a package ID).

FIG. 9B is an enlarged view of the specific information reading region 21 shown in FIG. 9A. As shown in FIG. 9B, a starting point pattern 22 is provided within the specific information reading region 21 so as to clearly indicate a starting point for measurement of the surface roughness of the package. In the present embodiment, the measurement of the surface roughness of the package in the specific information reading region 21 starts at the starting point pattern 22.

In the present embodiment, the surface roughness of the semiconductor package is evaluated by, for example, surface SEM analysis (analysis by a secondary electronic scanning electron microscope), thereby obtaining an image shown in FIG. 9C, for example. FIG. 9C is a plan view showing the surface roughness of the package in a region encircled by the bold line in the specific information region 21 shown in FIG. 9B, and FIG. 9D is a section taken along the line A-A′ in FIG. 9C. In the present embodiment, the resin package 16 is formed of a plastic resin containing a silicon filler to form a rough part 23 in a micro level (μm order) in the surface portion of the package, as shown in FIG. 9C and FIG. 9D. An image of the aspect of the rough part 23 is obtained by a surface SEM.

Further, in the present embodiment, the thus obtained image of the aspect of the surface roughness of the semiconductor package, which serves as the physically random specific information, is subjected to edge extraction by image processing to use the result as a package ID. FIG. 9E shows data (data expressing the contour of an edge 23a of the rough part 23 on the X-Y coordinates) obtained by the edge extraction from the image shown in FIG. 9C.

The reason why the edge extraction is performed to the image obtained by a surface SEM (hereinafter referred to as a surface SEM image) is as follows. Namely, in the case where the physically random specific information is utilized for setting IDs of individual semiconductor packages, the surface SEM image itself may be used as an ID. However, the direct use of the surface SEM image as an ID increases the amount of image data. In contrast, when the data obtained by employing a scheme of edge extraction from the surface SEM image is used as an ID, the data amount is contracted (compacted), attaining efficient storage and comparison of the package ID.

In the present embodiment, as described above, the data obtained by edge extraction, for example, the data shown in FIG. 9E is used as novel specific information having physically random characteristic unique to the semiconductor package to be measured and evaluated, namely, is used as a package ID.

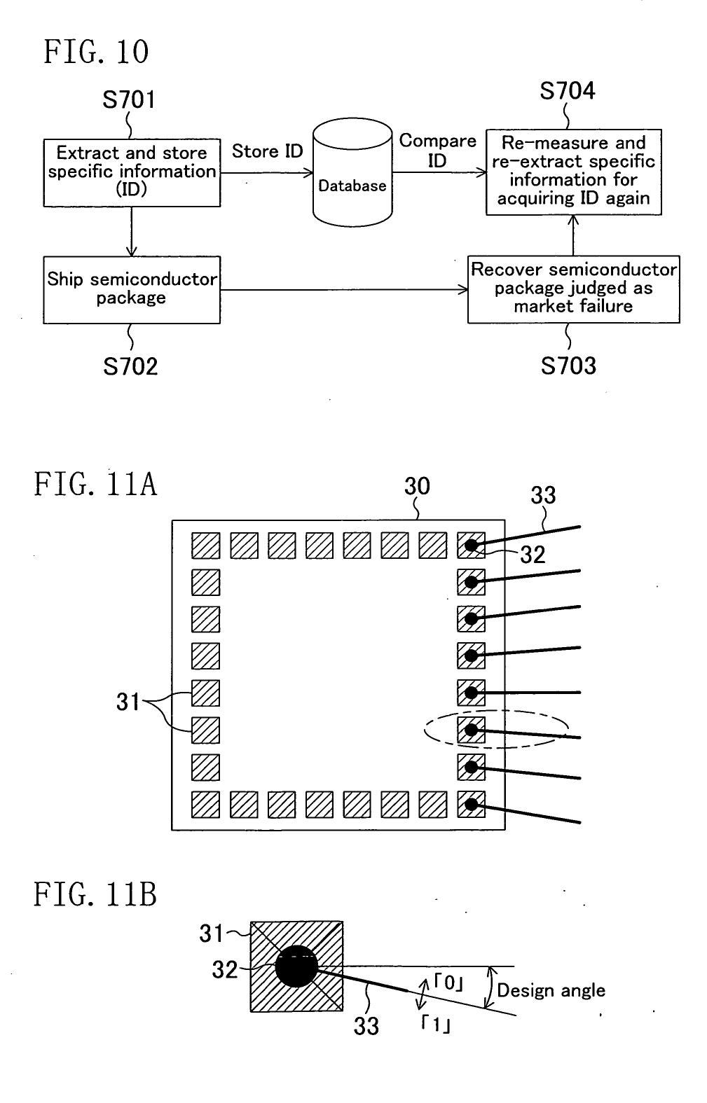

FIG. 10 shows a flow of the ID recognition method of a semiconductor package (specifically, a semiconductor package including a semiconductor integrated circuit) according to Embodiment 7.

First, in a step S701, specific information of individual semiconductor packages is measured and extracted for generating package IDs as described above, followed by storage of the obtained package IDs into a database provided in a memory device of a computer. In this time, manufacture information on the semiconductor packages (a manufacturing factory, a manufacturing line, manufacturing date, a lot number, a wafer number, and a chip number) or information on the semiconductor chips packaged in the semiconductor packages (time when the diffusion process is performed for the semiconductor chip, a lot number, a wafer number, a chip address in the wafer, and the like) is stored into the database together with the package IDs.

Thereafter, in a step S702, the semiconductor packages for which the package IDs are set are shipped as products as usual.

No problem is involved when the semiconductor package shipped as a product operates normally. While, when it is judged as a market failure, the failed semiconductor package is recovered in a step S703 to examine it to find a failure cause. Because, immediate failure cause fining and provision of countermeasures thereof are natural duties and responsibility which current companies considering customers first might have.

Specifically, the surface roughness of the package, which serves as the physically random specific information, in the specific information reading region 21 of the semiconductor package shown in FIG. 9A is measured again (re-evaluation using a surface SEM in the present embodiment). Subsequently, the thus measured and extracted surface roughness of the package is compared with the package ID that has been stored in the database prior to the product shipment to acquire again the package ID of the semiconductor package. Whereby, the information on the semiconductor chip packaged in the semiconductor package (time when the diffusion process is performed for the semiconductor chip, a lot number, a wafer number, a chip address in the wafer, and the like) can be acquired immediately based on the re-acquired package ID, enabling immediate failure cause fining. Further, the package ID is set using the physically random specific information, so that only the company that manufactured the semiconductor package can acquire again the various kinds of information on the semiconductor package including the package ID.

As described above, in the present embodiment, the surface roughness of the semiconductor package is utilized as the specific information, so that the specific information becomes distinctive and physically random. In consequence, an unforgeable package ID exhibiting a high-level information security function can be assigned to a semiconductor package based on the specific information. In other words, an unforgeable semiconductor package (a semiconductor package including a semiconductor integrated circuit chip) exhibiting a high-level information security function can be provided.

Further, for immediately providing countermeasures for customers' benefits upon market failure of a semiconductor package, the package ID is re-extracted by measuring again the surface roughness of the package as the physically random specific information, enabling speedy failure cause finding. In addition, the package ID of the present embodiment is set based on a topographic characteristic of a semiconductor package, so that the package ID of a semiconductor package electrically inoperable due to market failure can be re-extracted independently from the electric circuit operation of the semiconductor package.

Thus, the effects of the present invention are significant.

In the present embodiment, it is needless to say that the method for generating an ID from the surface roughness of the package is not limited to edge extraction by image processing.

### Embodiment 8

A semiconductor package ID recognition method according to Embodiment 8 of the present invention will be described below with reference to the drawings.

The most significant feature of the present embodiment lies in that lead angles of lead wires (bonding wires) in a semiconductor package (directions that the bonding wires extend from bonding pads) are set as the physically random specific information.

FIG. 11A shows an aspect of a semiconductor integrated circuit chip packaged in a semiconductor package used in the present embodiment as viewed from the obverse side.

As shown in FIG. 11A, bonding pads 31 to which bonding wires 33 are connected are provided on the surface of a semiconductor integrated circuit chip 30. One end of each bonding wire 33 is mounted to the corresponding bonding pad 31 through a bonding portion 32. Though not shown, the other end of the bonding wire 33 is connected to an external terminal of the semiconductor package.

In the present embodiment, the lead angles of the bonding wires 33 are utilized as the physically random specific information and the package ID is set based on deviation of the specific information from a design value.

Specifically, as shown in FIG. 11B, “0” is set when the bonding wire 33 deviates leftward from a design angle as viewed from the bonding portion 32 while “1” is set when the bonding wire 33 deviates rightward from the design angle as viewed from the bonding portion 32. Recent general semiconductor integrated circuit chips have about 100 to 300 pads. Supposing that the number of the pads in the present embodiment is 100, for example, the aforementioned “0/1” setting can offer 10³⁰ or more numerical values, enabling setting of an intimate package ID based on the lead angles of the bonding wires as the physically random specific information.

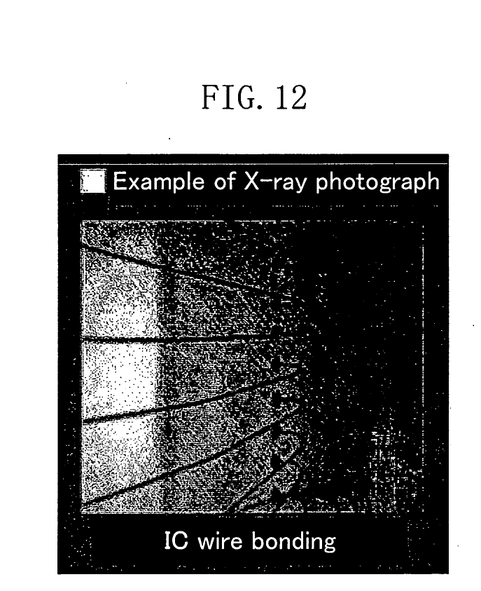

In the present embodiment, each lead angle of the bonding wires is measured by radioscopy first. FIG. 12B is an X-ray photograph as one example of the bonding wires. Next, as shown in FIG. 11B, each deviation of the lead angles of the bonding wires from the design value is converted into a numerical value based on the thus obtained image information on the lead angles of the bonding wires, thereby setting a package ID.

As described above, after the package IDs are set for individual semiconductor packages, the thus obtained package IDs are stored in a database provided in a memory device of a computer, likewise the case of Embodiment 7. In this time, manufacture information on the semiconductor packages (a manufacturing factory, a manufacturing line, manufacturing date, a lot number, a wafer number, and a chip number) or information on the semiconductor chips packaged in the semiconductor packages (time when the diffusion process is performed for the semiconductor chip, a lot number, a wafer number, a chip address in the wafer, and the like) is stored into the database together with the package IDs.

Thereafter, the semiconductor packages for which the package IDs are set are shipped as products as usual.

When a semiconductor package shipped as a product is judged as a market failure, the failed semiconductor package is recovered to examine it to find a failure cause. Specifically, the lead angles of the bonding wires in the failed semiconductor package, which serve as the physically random specific information, are measured (re-evaluation using radioscopy in the present embodiment) again. Subsequently, each measured and extracted lead angle of the bonding wires is converted into a numerical value, as shown in FIG. 11B, and the thus converted numerical values are compared with the package ID that has been stored in the database prior to the product shipment, thereby acquiring the package ID of the semiconductor package again. Whereby, the information on the semiconductor chip packaged in the semiconductor package (time when the diffusion process is performed for the semiconductor chip, a lot number, a wafer number, a chip address in the wafer, and the like) can be acquired immediately based on the re-acquired package ID, enabling speedy failure cause fining. Further, the package ID is set using the physically random specific information, so that only the company that manufactured the semiconductor package can acquire again the various kinds of information on the semiconductor package including the package ID.

As described above, in the present embodiment, each lead angle of bonding wires in a semiconductor package is utilized as the specific information, so that that the specific information becomes distinctive and physically random. In consequence, an unforgeable package ID exhibiting a high-level information security function can be assigned to a semiconductor package based on the specific information. In other words, an unforgeable semiconductor package (a semiconductor package including a semiconductor integrated circuit chip) exhibiting a high-level information security function can be provided. Further, for immediately providing countermeasures for customers' benefits upon market failure of a semiconductor package, the package ID is re-extracted by measuring again the lead angles of the bonding wires as the physically random specific information, enabling speedy failure cause finding. In addition, the package ID of the present embodiment is set based on a topographic characteristic of a semiconductor package, so that the package ID of a semiconductor package electrically inoperable due to market failure can be re-extracted independently from the electric circuit operation of the semiconductor package. Thus, the effects of the present invention are significant.

In the present embodiment, it is needless to say that the method for generating an ID from lead angles of bonding wires is not limited to the numerical value conversion as shown in FIG. 11B. For example, image information showing the lead angles of a plurality of bonding wires may be used directly as a package ID, of course.

### Embodiment 9

A semiconductor package ID recognition method according to Embodiment 9 of the present invention will be descried with reference to the drawings.

The most significant feature of the present embodiment lies in that the contour of a bonding portion (a portion for connecting a bonding wire and a bonding pad) in a semiconductor package is utilized as the physically random specific information.

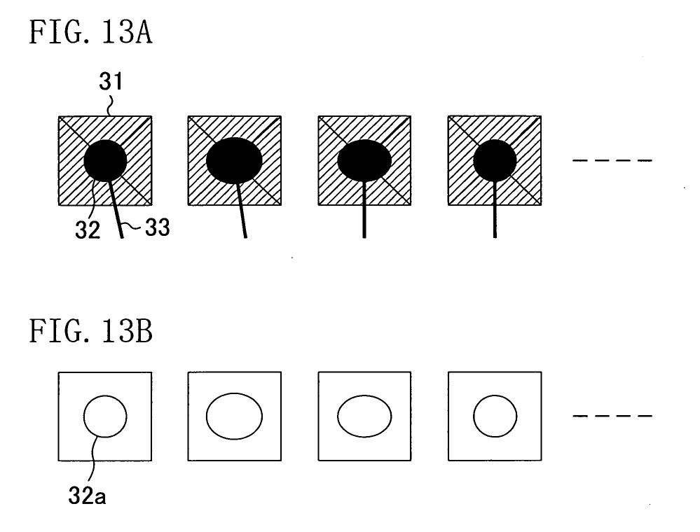

FIG. 13A shows bonding portions 32 (plural) in plan on a semiconductor integrated circuit chip packaged in a semiconductor package used in the present embodiment. As shown in FIG. 13A, bonding wires 33 are mounted to bonding pads 31 through the bonding portions 32.

In the present embodiment, first, the aspect of the bonding portions to serve as the specific information are shot by a microscope, a surface SEM, or the like and the thus shot image is subjected to image processing so that the edge contours 32a of the bonding portions 32 are extracted as shown in FIG. 13B. In the present embodiment, the thus extracted data (the edge contours of the bonding portions) is used as a package ID.

After the package IDs are set for individual semiconductor packages as described above, the thus obtained package IDs are stored in a database provided in a memory device of a computer, likewise the case of Embodiment 7. In this time, manufacture information on the semiconductor packages (a manufacturing factory, a manufacturing line, manufacturing date, a lot number, a wafer number, and a chip number) or information on the semiconductor chips packaged in the semiconductor packages (time when the diffusion process is performed for the semiconductor chip, a lot number, a wafer number, a chip address in the wafer, and the like) is stored into the database together with the package IDs.

Thereafter, the semiconductor packages for which the package IDs are set are shipped as products as usual.

When a semiconductor package shipped as a product is judged as a market failure, the failed semiconductor package is recovered to examine it to find a failure cause. Specifically, each contour of the bonding portions in the failed semiconductor package, which serves as the physically random specific information, is measured again (re-evaluation using a microscope or a surface SEM in the present embodiment). Subsequently, each contour of the bonding portions thus measured and extracted is compared with the package ID that has been stored in the database prior to the product shipment to acquire again the package ID of the semiconductor package. Whereby, the information on the semiconductor chip packaged in the semiconductor package (time when the diffusion process is performed for the semiconductor chip, a lot number, a wafer number, a chip address in the wafer, and the like) can be acquired immediately based on the re-acquired package ID, enabling speedy failure cause fining. Further, the package ID is set using the physically random specific information, so that only the company that manufactured the semiconductor package can acquire again the various kinds of information on the semiconductor package including the package ID.

As described above, in the present embodiment, each contour of bonding portions in a semiconductor package is utilized as the specific information, so that the specific information becomes distinctive and physically random. In consequence, an unforgeable package ID exhibiting a high-level information security function can be assigned to a semiconductor package based on the specific information. In other words, an unforgeable semiconductor package (a semiconductor package including a semiconductor integrated circuit chip) exhibiting a high-level information security function can be provided. Further, for immediately providing countermeasures for customers' benefits upon market failure of a semiconductor package, the package ID is re-extracted by measuring again the contours of the bonding portions as the physically random specific information, enabling speedy failure cause finding. In addition, the package ID of the present embodiment is set based on a topographic characteristic of a semiconductor package, so that the package ID of a semiconductor package electrically inoperable due to market failure can be re-extracted independently from the electric circuit operation of the semiconductor package. Thus, the effects of the present invention are significant.

In the present embodiment, it is needless to say that the method for generating an ID from the contours of the bonding portions is not limited to edge extraction by image processing.

### Embodiment 10

A semiconductor package ID recognition method according to Embodiment 10 of the present invention will be described below with reference to the drawings.

The most significant feature of the present embodiment lies in that the shape of a bump in a semiconductor package is utilized as the physically random specific information.

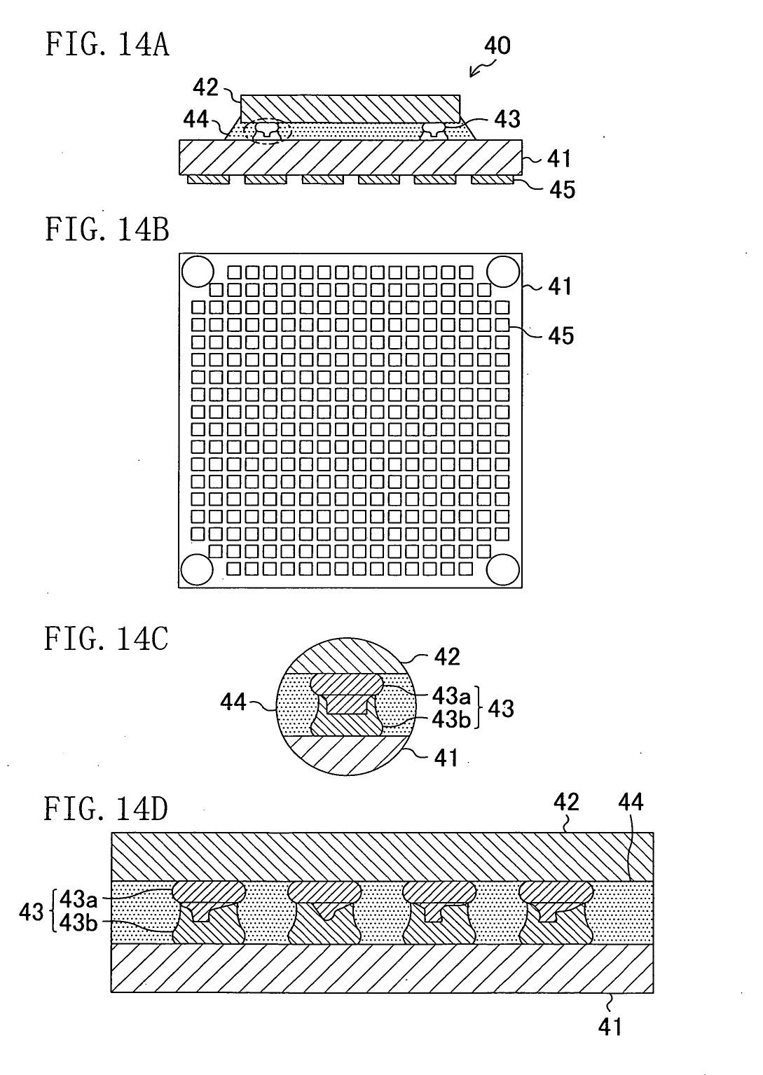

FIG. 14A shows a construction in section of a semiconductor package used in the present embodiment, specifically, a package called a ceramic CSP (C-CSP). As shown in FIG. 14A, for the purpose of compact packaging, a ceramic interposer 41 and a semiconductor integrated circuit chip 42 are connected with each other by means of bumps 43 in the C-CSP 40 of the present embodiment. Namely, no lead wire is used. A resin 44 is filled between the ceramic interposer 41 and the semiconductor integrated circuit chip 42. Further, an external terminal 45 is provided on a face opposite the face of the ceramic interposer 41 where the semiconductor integrated circuit chip 42 is mounted. FIG. 14B shows an aspect of the C-CSP shown in FIG. 14A as viewed from the reverse side (the external terminal side). FIG. 14C and FIG. 14D show the detailed structures of the bumps 43 between the ceramic interposer 41 and the semiconductor integrated circuit chip 42. In the present embodiment, the bumps 43 are made of gold (Au). Specifically, as shown in FIG. 14C and FIG. 14D, after Au bumps 43a are formed on pads (not shown) on the semiconductor integrated circuit chip 42, leveling is performed to align the height of all the Au bumps 43a. Then, Ag—Pd paste 43b is allowed to adhere to each of the Au bumps 43a to connect the ceramic interposer 41 and the semiconductor integrated circuit chip 42 with each other by means of the bumps 43. Thereafter, the resin 44 is filled between the ceramic interposer 41 and the semiconductor integrated circuit chip 42 to fix the semiconductor integrated circuit 42.

In the present embodiment, each shape of the bumps 43 (Au bumps 43a) of the C-CSP 40 formed as above is utilized as the physically random specific information. The reason why the shapes of the bumps 43 are utilized is that, as shown in FIG. 14D, the Au bumps 43a have individually random shapes different from one another.

In the present embodiment, first, the shapes of the Au bumps 43A, which serve as the physically random specific information, are measured and evaluated by radioscopy. The radioscopy can project the side of a package with the X-ray, which means that each shape of the bumps can be measured even after completion of the C-CSP. In the present embodiment, data of the thus extracted bump shapes or data thereof subjected to image processing is utilized as a package ID.

After package IDs are set for individual semiconductor packages as described above, the thus obtained package IDs are stored in a database provided in a memory device of a computer, likewise the case of Embodiment 7. In this time, manufacture information on the semiconductor packages (a manufacturing factory, a manufacturing line, manufacturing date, a lot number, a wafer number, and a chip number) or information on the semiconductor chips packaged in the semiconductor packages (time when the diffusion process is performed for the semiconductor chip, a lot number, a wafer number, a chip address in the wafer, and the like) is stored into the database together with the package IDs.

When a semiconductor package shipped as a product is judged as a market failure, the failed semiconductor package is recovered to examine it to find a failure cause.

Specifically, the shapes of the bumps in the failed semiconductor package, which serve as the physically random specific information, are measured again (re-evaluation by radioscopy in this present embodiment). Subsequently, each bump shape thus measured and extracted is compared with the package ID that has been stored in the database prior to the product shipment to acquire again the package ID of the semiconductor package.

Whereby, the information on the semiconductor chip packaged in the semiconductor package (time when the diffusion process is performed for the semiconductor chip, a lot number, a wafer number, a chip address in the wafer, and the like) can be acquired immediately based on the re-acquired package ID, enabling speedy failure cause fining.

Further, the package ID is set using the physically random specific information, so that only the company that manufactured the semiconductor package can acquire again the various kinds of information on the semiconductor package including the package ID. As described above, in the present embodiment, the shapes of the bumps in the semiconductor package are utilized as the specific information, so that the specific information becomes distinctive and physically random. In consequence, an unforgeable package ID exhibiting a high-level information security function can be assigned to a semiconductor package based on the specific information. In other words, an unforgeable semiconductor package (a semiconductor package including a semiconductor integrated circuit chip) exhibiting a high-level information security function can be provided.

Further, for immediately providing countermeasures for customers' benefits upon market failure of a semiconductor package, the package ID is re-extracted by measuring again the shapes of the bumps as the physically random specific information, enabling speedy failure cause finding. In addition, the package ID of the present embodiment is set based on a topographic characteristic of a semiconductor package, so that the package ID of a semiconductor package electrically inoperable due to market failure can be re-extracted independently from the electric circuit operation of the semiconductor package. Thus, the effects of the present invention are significant.

### Embodiment 11

A semiconductor integrated circuit chip (a semiconductor device) according to Embodiment 11 of the present invention will be described below with reference to the drawings. While the package ID assignment to a semiconductor package has been described in Embodiments 5 to 10, assignment of a chip ID to a semiconductor integrated circuit chip will be described in the present embodiment and the following embodiments. Specifically, a topographic characteristic that a semiconductor integrated circuit chip has is utilized as the physically random specific information.

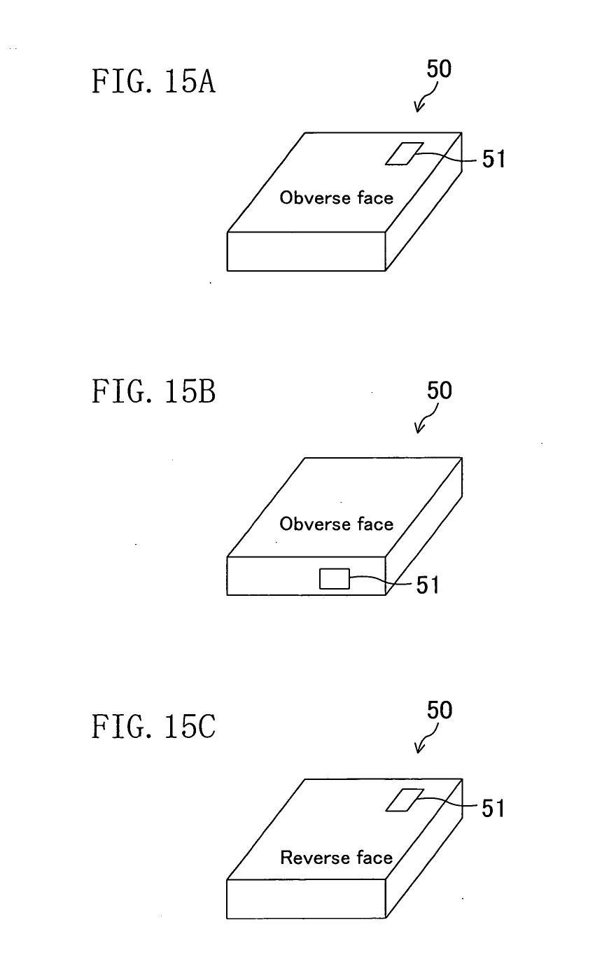

FIG. 15A to FIG. 15C are perspective views showing a variety of semiconductor integrated circuit chips according to Embodiment 11.

In a semiconductor integrated circuit chip 50 shown in FIG. 15A, a specific information reading region 51 for measuring the topographic characteristic of the obverse face of the chip as the specific information for generating a chip ID is provided in the obverse face of the chip.

In a semiconductor integrated circuit chip 50 shown in FIG. 15B, a specific information reading region 51 for measuring the topographic characteristic of a side face of the chip as the specific information for generating a chip ID is provided in one side face of the chip.

In a semiconductor integrated circuit chip 50 shown in FIG. 15C, a specific information reading region 51 for measuring the topographic characteristic of the reverse face of the chip as the specific information for generating a chip ID is provided in the reverse face of the chip.

The semiconductor integrated circuit chips (semiconductor devices) shown in FIG. 15A to FIG. 15C lead to easy acquisition of the topographic characteristic that the semiconductor integrated circuit chips have as the specific information, as described in Embodiment 12 and the following embodiments.

### Embodiment 12

A semiconductor integrated circuit chip (a semiconductor device) according to Embodiment 12 of the present invention will be described below with reference to the drawings.

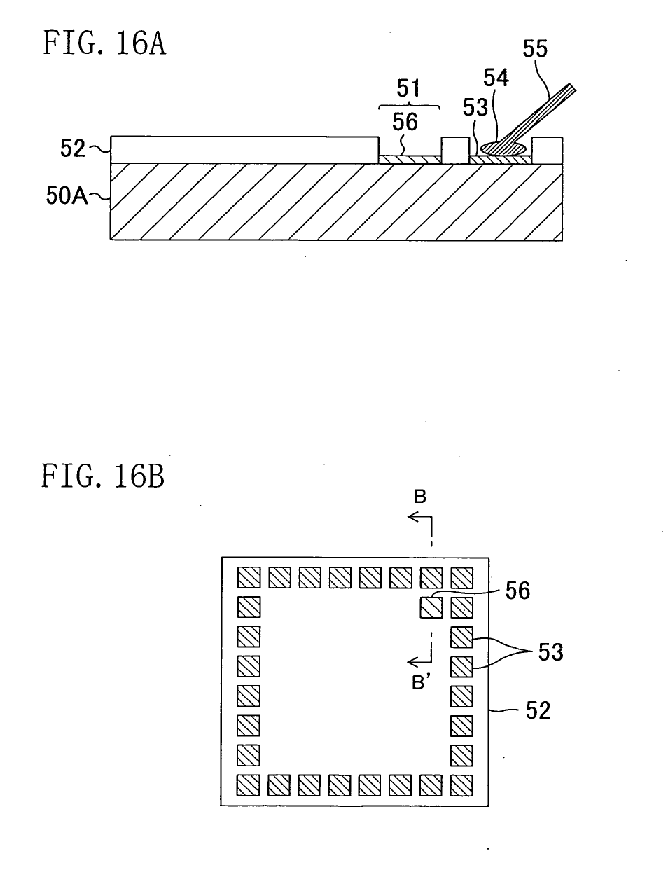

FIG. 16A and FIG. 16B are a sectional view and a plan view, respectively, of the semiconductor integrated circuit chip according to Embodiment 12. Wherein, FIG. 16A is a sectional view taken along the line B-B′ in FIG. 16B.

As shown in FIG. 16A and FIG. 16B, the surface of a substrate 50A serving as a semiconductor integrated circuit chip is covered with a passivation film 52 made of polyimide or the like. An opening portion for exposing a bonding pad 53 on the substrate 50A is formed in the passivation film 52. In packaging the semiconductor integrated circuit chip, a bonding wire 55 is mounted to a bonding pad 53 through a bonding portion 54, as shown in FIG. 16A, or a bump is provided on the bonding pad 53.

The most significant feature of the present embodiment lies in that the opening portion for exposing at least a part of a metal film (for example, a Cu film, an Al film, and the like) 56 composing a wire on the substrate 50A is formed in the passivation film 52 so that a grain boundary of the surface of the metal film can be observed. Specifically, in the semiconductor integrated circuit chip of the present embodiment, a specific information reading region 51 for measuring the shape of the grain boundary of the metal film 56 as the specific information for generating a chip ID is provided on the surface of the chip. Wherein, neither a lead wire (bonding wire) nor a bump is connected to the metal film 56 exposed in the specific information reading region 51, that is, a pattern for grain boundary observation.

In this way, in the present embodiment, in order to measure the grain boundary of the metal film 56 as the physically random specific information of the semiconductor integrated circuit chip and assign the specific chip ID based on the measured result, the metal film 56 as a pattern for grain boundary observation is exposed in the specific information reading region 51, resulting in easy observation of the grain boundary.

It is noted that the material of the metal film 56 is not specified particularly and copper (Cu), aluminum (Al), tungsten (W), or an alloy containing at least two of them may be used.

In addition, in the present embodiment, if the specific information reading region 51 is provided in a region other than the region on the surface of the chip where the bonding pad 53 is formed, measurement of the grain boundary is further facilitated.

### Embodiment 13

A semiconductor integrated circuit chip (a semiconductor device) according to Embodiment 13 of the present invention will be described below with reference to the drawings.

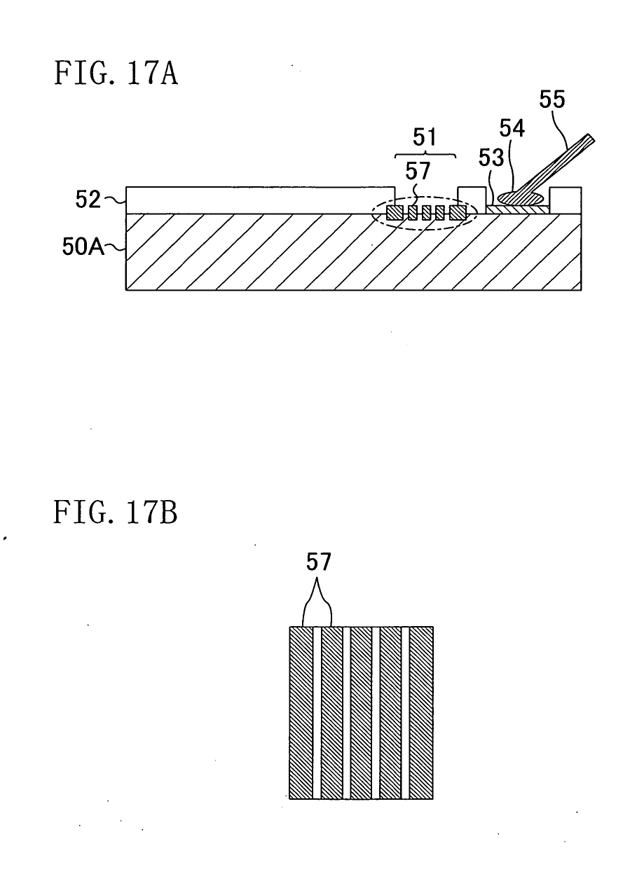

FIG. 17A is a sectional view of the semiconductor integrated circuit chip according to Embodiment 13.

Similar to Embodiment 12, the surface of a substrate 50A serving as the semiconductor integrated circuit chip is covered with a passivation film 52 made of polyimide or the like, as shown in FIG. 17A. An opening portion for exposing a bonding pad 53 on the substrate 50A is formed in the passivation film 52. In packaging the semiconductor integrated circuit chip, a bonding wire 55 is mounted to a bonding pad 53 through a bonding portion 54, as shown in FIG. 17A, or a bump is provided on the bonding pad 53.

The most significant feature of the present embodiment lies in that a wire 57 is formed for observation of the edge outline thereof after being etched and the opening portion for exposing at least a part of the wire 57 is formed in the passivation film 52 so that the edge outline of the wire 57 can be observed. Specifically, in the semiconductor integrated circuit chip of the present embodiment, a specific information reading region 51 for measuring the edge outline of the wire 57 as the specific information for generating a chip ID is provided on the surface of the chip. FIG. 17B is a plan view in an enlarged scale showing the wire 57 exposed in the specific information reading region (a wire edge outline observation region) 51.

In this way, in the present embodiment, in order to measure the edge outline of the wire 57 as the physically random specific information of the semiconductor integrated circuit chip and assign the specific chip ID based on the measured result, the wire 57 as a pattern for wire edge outline observation is exposed in the specific information reading region 51, resulting in easy observation of the edge outline.

It is noted that the material of the wire 57 is not specified particularly and Cu, Al, W, or an alloy containing at least two of them may be sued.

In addition, in the present embodiment, if the specific information reading region 51 is provided in a region other than the region on the surface of the chip where the bonding pad 53 is formed, measurement of the edge outline is further facilitated.

### Embodiment 14

A semiconductor integrated circuit chip ID recognition method according to Embodiment 14 of the present invention will be described below with reference to the drawings.

Wherein, a semiconductor integrated circuit chip (a semiconductor device) used in the present embodiment is the same as the semiconductor integrated circuit chip (see FIG. 16A and FIG. 16B) including the specific information reading region 51 where the surface of the metal film 56 is exposed, as described in Embodiment 12.

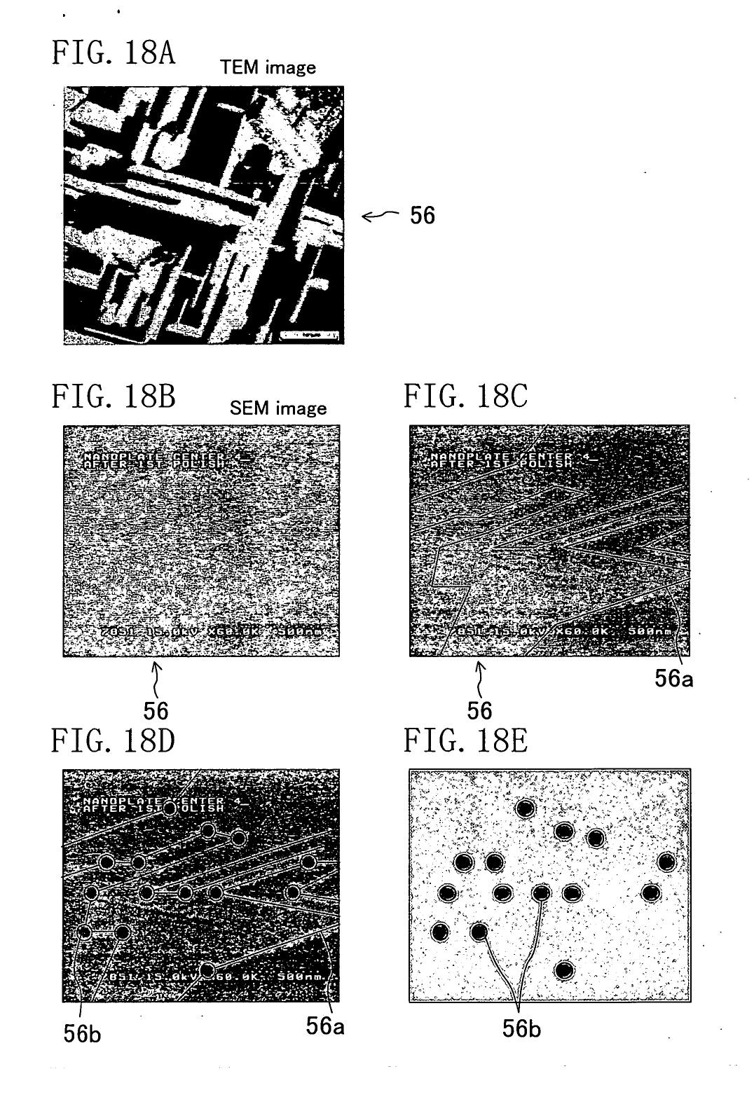

FIG. 18A shows a result obtained by observing by a TEM (a transmission electron microscope) the surface of the metal film 56, specifically, a Cu (copper) film used as a wire material in a semiconductor integrated circuit chip. Wherein, Cu has a grain boundary, which is physically random. Also, Al, Poly-Si (polysilicon) and the like to be used as the wire materials other than Cu have grain boundaries that are physically random.

In the present embodiment, the metal film 56 exposed in the specific information reading region 51 in the semiconductor integrated circuit chip (see FIG. 16A and FIG. 16B) described in Embodiment 12 was observed by a surface SEM. FIG. 18B shows a result (a photo) obtained by observing a Cu film serving as the metal film 56 by the surface SEM. It is understood from FIG. 18B that the surface SEM can shoot the grain boundary of Cu clearly, as well. It is noted that surface treatment to the Cu film using a diluted HF solution attains further clear observation of the grain boundary of Cu. Also, in the present embodiment, for example, an AFM or the like may be used rather than the surface SEM for measuring the grain boundary (strictly, a step on the grain boundary).

In the semiconductor integrated circuit chip ID recognition method according to the present embodiment, the grain boundary of the metal film 56 provided in the semiconductor integrated circuit chip is measured as the physically random specific information, followed by assignment of a chip ID to the semiconductor integrated circuit chip based on the measured value.

Specifically, as described above, the surface SEM observation is performed first to obtain a surface SEM photo of the grain boundaries of the metal (Cu) film 56, which serve as the specific information of the semiconductor integrated circuit chip. Then, the grain boundaries 56a of the metal (Cu) film 56 are extracted, as shown in FIG. 18C, by subjecting the surface SEM photo to image processing. Further, in the present embodiment, points 56b that connect the extracted grain boundaries with each other are extracted, as shown in FIG. 18D, and the positional information of the points 56b shown in FIG. 18E is utilized as a chip ID.

After the chip IDs are set for individual semiconductor integrated circuit chips as described above, the thus obtained chip IDs are stored in a database provided in a memory device of a computer, likewise the case of Embodiment 7. In this time, information on the chips (time when the diffusion process is performed for the semiconductor chip, a lot number, a wafer number, a chip address in the wafer, and the like) is stored into the database together with the chip IDs.

Thereafter, the semiconductor integrated circuit chips for which the chip IDs are set are shipped as products as usual.

When a semiconductor integrated circuit chip shipped as a product is judged as a market failure, the failed semiconductor integrated circuit chip is recovered to examine it to find a failure cause. Specifically, the grain boundary of the metal film 56, which serves as the physically random specific information, is measured again (re-evaluation using a surface SEM in the present embodiment). Subsequently, the grain boundary thus measured and extracted is compared with the chip ID that has been stored in the database prior to the product shipment to acquire again the chip ID of the semiconductor integrated circuit chip. Whereby, the information on the semiconductor chip (time when the diffusion process is performed for the semiconductor chip, a lot number, a wafer number, a chip address in the wafer, and the like) can be acquired immediately based on the re-acquired chip ID, enabling speedy failure cause fining. Further, the chip ID is set using the physically random specific information, so that only the company that manufactured the semiconductor package can acquire again the various kinds of information on the semiconductor chip including the chip ID.

As described above, in the present embodiment, the grain boundary of the metal film in the semiconductor integrated circuit chip is utilized as the specific information, so that the specific information becomes distinctive and physically random. In consequence, an unforgeable chip ID exhibiting a high-level information security function can be assigned to a semiconductor integrated circuit chip based on the specific information. In other words, an unforgeable semiconductor integrated circuit chip exhibiting a high-level information security function can be provided. Further, for immediately providing countermeasures for customers' benefits upon market failure of a semiconductor integrated circuit chip, the chip ID is re-extracted by measuring again the grain boundary of the metal film as the physically random specific information, enabling speedy failure cause finding. In addition, the chip ID of the present embodiment is set based on a topographic characteristic of a semiconductor integrated circuit chip, so that the chip ID of a semiconductor integrated circuit chip electrically inoperable due to market failure can be re-extracted independently from the electric circuit operation of the semiconductor integrated circuit chip. Thus, the effects of the present invention are significant.

In the present embodiment, it is needless to say that the method for generating an ID from a grain boundary of a metal film is not limited to the method by image processing.

### Embodiment 15

A semiconductor integrated circuit chip ID recognition method according to Embodiment 15 of the present invention will be described below with reference to the drawings.

Wherein, a semiconductor integrated circuit chip (a semiconductor device) used in the present embodiment is the same as the semiconductor integrated circuit chip (see FIG. 17A and FIG. 17B) including the specific information reading region 51 where the surface of the metal film 57 is exposed, as described in Embodiment 13.

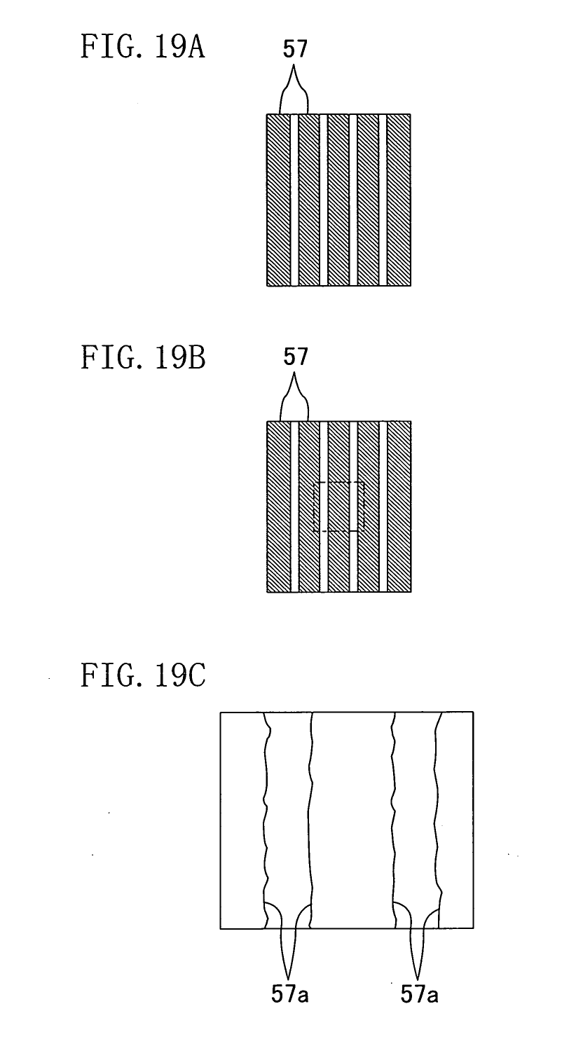

FIG. 19A shows a construction in plan of a wire 57 exposed in the specific information reading region 51. FIG. 19B show a wire edge outline observation region (a region encircled by the dash-dot line in the drawing) of the wire 57 shown in FIG. 9A.

In short, in the present embodiment, the edge outline (rough outline of the edge portion) of the wire (metal wire) 57 is utilized as the physically random specific information and a chip ID is set based on the numerical value of the edge outline.

In the semiconductor integrated circuit chip in Embodiment 13, which is used also in the present embodiment, the wire 57 for observation of the edge outline thereof after being etched is formed and the opening portion through which at least a part of the wire 57 is exposed is formed in the passivation film 52 in a wire formation process so that the edge outline of the wire 57 can be observed. In short, a specific information reading region 51 for measuring the edge outline of the wire 57 as specific information for generating a chip ID is provided on the surface of the chip.

In the present embodiment, the wire 57 exposed in the specific information reading region 51 of the semiconductor integrated circuit chip (see FIG. 17A and FIG. 17B), as described in Embodiment 13, is observed by a surface SEM. Then, the surface SEM image (see FIG. 19B) is subjected to image processing to extract an edge outline 57a of the wire 57 so that the thus extracted edge outline 57a is used as a chip ID.

After the chip IDs are set for individual semiconductor integrated circuit chips as described above, the thus obtained chip IDs are stored in a database provided in a memory device of a computer, likewise the case of Embodiment 7. In this time, information on the chips (time when the diffusion process is performed for the semiconductor chip, a lot number, a wafer number, a chip address in the wafer, and the like) is stored into the database together with the chip IDs.

Thereafter, the semiconductor integrated circuit chips for which the chip IDs are set are shipped as products as usual.

When a semiconductor integrated circuit chip shipped as a product is judged as a market failure, the failed semiconductor integrated circuit chip is recovered to examine it to find a failure cause. Specifically, the edge outline of the wire 57, which serves as the physically random specific information, is measured again (re-evaluation using a surface SEM in the present embodiment). Subsequently, the edge outline thus measured and extracted is compared with the chip ID that has been stored in the database prior to the product shipment to acquire again the chip ID of the semiconductor integrated circuit chip. Whereby, the information on the semiconductor chip (time when the diffusion process is performed for the semiconductor chip, a lot number, a wafer number, a chip address in the wafer, and the like) can be acquired immediately based on the re-acquired chip ID, enabling speedy failure cause fining. Further, the chip ID is set using the physically random specific information, so that only the company that manufactured the semiconductor chip can acquire again the various kinds of information on the semiconductor chip including the chip ID.

As described above, in the present embodiment, the edge outline of a wire in a semiconductor integrated circuit chip is utilized as the specific information, so that the specific information becomes distinctive and physically random. In consequence, an unforgeable chip ID exhibiting a high-level information security function can be assigned to a semiconductor integrated circuit chip based on the specific information. In other words, an unforgeable semiconductor integrated circuit chip exhibiting a high-level information security function can be provided. Further, for immediately providing countermeasures for customers' benefits upon market failure of a semiconductor integrated circuit chip, the chip ID is re-extracted by measuring again the edge outline of the wire as the physically random specific information, enabling speedy failure cause finding. In addition, the chip ID of the present embodiment is set based on a topographic characteristic of a semiconductor integrated circuit chip, so that the chip ID of a semiconductor integrated circuit chip electrically inoperable due to market failure can be re-extracted independently from the electric circuit operation of the semiconductor integrated circuit chip. Thus, the effects of the present invention are significant.

In the present embodiment, it is needless to say that the method for extracting an edge outline of a wire is not limited to the method by image processing.

### Embodiment 16

A semiconductor integrated circuit chip ID recognition method according to Embodiment 16 of the present invention will be described below with reference to the drawings.

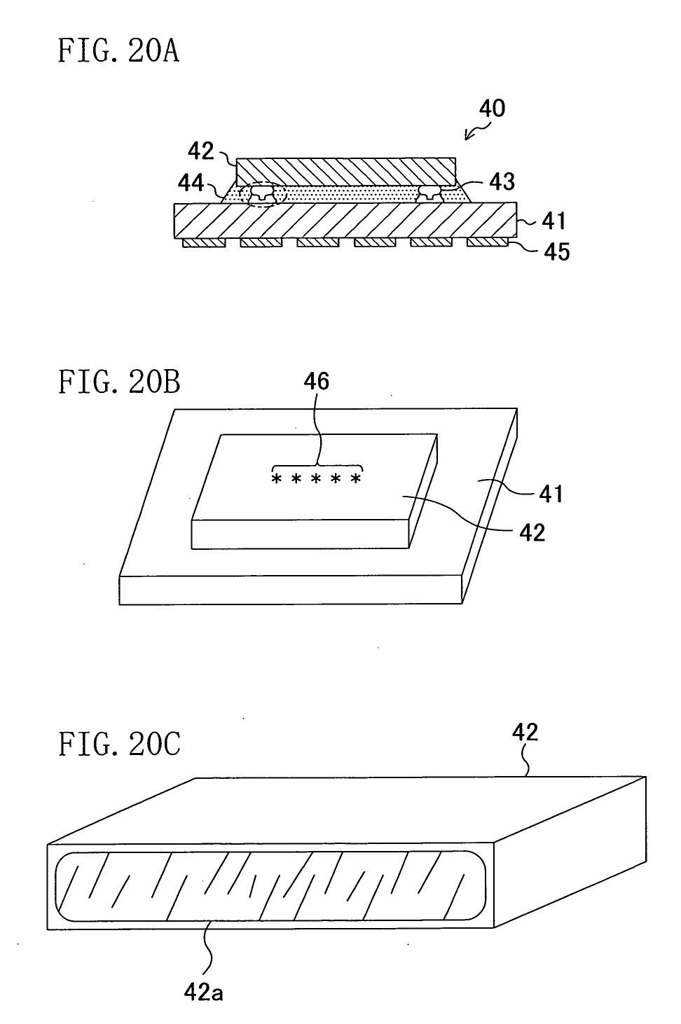

FIG. 20A shows a construction in section of a semiconductor package used in the present embodiment, specifically, a package called a C-CSP just the same as that shown in FIG. 14A in Embodiment 10. Also, FIG. 20B is a view showing the surface of the semiconductor package shown in FIG. 20A as viewed obliquely from above. Wherein, in FIG. 20A and FIG. 20B, the same reference numerals are assigned to the same members as those in FIG. 14A and the description thereof is omitted.

As shown in FIG. 20B, the semiconductor integrated circuit chip 42 is mounted on the ceramic interposer 41 so that the reverse face thereof appears as the surface of the semiconductor package. The imprint portion 46 for the product number and the like of the semiconductor integrated circuit chip 42 is provided on this reverse face of the chip.

The most significant feature of the present embodiment lies in that, as shown in FIG. 20C, edge profile of roughness, chapping, flaws, and the like (hereinafter referred to as roughness and the like) generated in the side surface portion 24a of the semiconductor integrated circuit chip 42 in chip dicing is utilized as the physically random specific information and a chip ID is set based on a measurement value of the edge profile of the roughness and the like. The roughness and the like are generated when a semiconductor integrated circuit chip before being packaged is taken out from a wafer by dicing, and the profile of the side face of the chip, which is a diced face, can be observed by a microscope, a surface SEM, or the like.

In the present embodiment, a SEM image obtained by observing the chip side face by a surface SEM is subjected to image processing to extract the edge profile of the roughness and the like of the chip side face and the thus extracted edge profile is used as a chip ID.

After the chip IDs are set for individual semiconductor integrated circuit chips as described above, the thus obtained chip IDs are stored in a database provided in a memory device of a computer, likewise the case of Embodiment 7. In this time, information on the chips (time when the diffusion process is performed for the semiconductor chip, a lot number, a wafer number, a chip address in the wafer, and the like) is stored into the database together with the chip IDs.

Thereafter, the semiconductor integrated circuit chips for which the chip IDs are set are shipped as products as usual.

When a semiconductor integrated circuit chip shipped as a product is judged as a market failure, the failed semiconductor integrated circuit chip is recovered to examine it to find a failure cause. Specifically, the edge profile of the roughness and the like of the chip side face, which serves as the physically random specific information, is measured again (re-evaluation using a surface SEM in the present embodiment). Subsequently, the edge profile thus measured and extracted is compared with the chip ID that has been stored in the database prior to the product shipment to acquire again the chip ID of the semiconductor integrated circuit chip. Whereby, information on the chip (time when the diffusion process is performed for the semiconductor chip, a lot number, a wafer number, a chip address in the wafer, and the like) can be acquired immediately based on the re-acquired chip ID, enabling speedy failure cause fining. Further, the chip ID is set using the physically random specific information, so that only the company that manufactured the chip can acquire again the various kinds of information on the semiconductor chip including the chip ID.

As described above, in the present embodiment, the edge profile of the roughness and the like of the side face of a semiconductor integrated circuit chip which is generated in chip dicing is utilized as the specific information, so that the specific information becomes distinctive and physically random. In consequence, an unforgeable chip ID exhibiting a high-level information security function can be assigned to a semiconductor integrated circuit chip based on the specific information. In other words, an unforgeable semiconductor integrated circuit chip exhibiting a high-level information security function can be provided. Further, for immediately providing countermeasures for customers' benefits upon market failure of a semiconductor integrated circuit chip, the chip ID is re-extracted by measuring again the edge profile of the roughness and the like of the chip side face as the physically random specific information, enabling speedy failure cause finding. In addition, the chip ID of the present embodiment is set based on a topographic characteristic of a semiconductor integrated circuit chip, so that the chip ID of a semiconductor integrated circuit chip electrically inoperable due to market failure can be re-extracted independently from the electric circuit operation of the semiconductor integrated circuit chip. Thus, the effects of the present invention are significant.

In the present embodiment, it is needless to say that the method for extracting an edge profile of the roughness and the like of a chip side face is not limited to the method by image processing. Further, any topographic characteristic other than the edge profile of the roughness and the like may be utilized as the physically random specific information, of course.

### Embodiment 17

A semiconductor integrated circuit chip (a semiconductor device) according to Embodiment 17 will be described below with reference to the drawings.

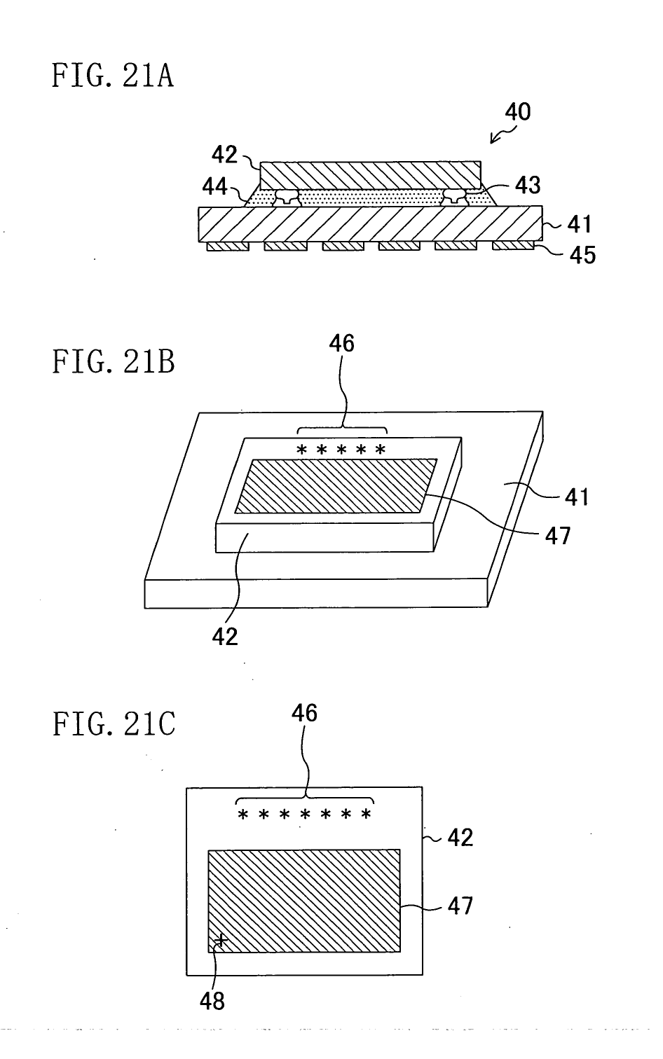

FIG. 21A is a section showing a state in which the semiconductor integrated circuit chip (the semiconductor integrated circuit chip 42) of the present embodiment is mounted in a semiconductor package called a C-CSP just the same as that shown in FIG. 14A in Embodiment 10. Further, FIG. 21B is a view of the surface of the semiconductor package shown in FIG. 21A as viewed obliquely from above. Wherein, in FIG. 21A and FIG. 21B, the same reference numerals are assigned to the same members as those in FIG. 14A and the description thereof is omitted.

As shown in FIG. 21B, the semiconductor integrated circuit chip 42 of the present embodiment is mounted on the ceramic interposer 41 so that the reverse face thereof appears as the surface of the semiconductor package. On the reverse face of the semiconductor integrated circuit chip 42, the imprint portion 46 for the product number and the like and the specific information reading region 47 for measuring a profile of the reverse face as the physically random specific information are provided, which is one of the significant features of the present embodiment. Further, as shown in FIG. 21C, a starting point pattern 48 for clearly indicating a measurement index of the reverse face profile is provided in the specific information reading region 47 on the reverse face of the semiconductor integrated circuit chip 42.

According to the semiconductor integrated circuit chip of the present embodiment, a semiconductor integrated circuit chip ID recognition method according to Embodiment 18, which is described next, can be reduced into practice.

### Embodiment 18

A semiconductor integrated circuit chip ID recognition method according to Embodiment 18 of the present invention will be described below with reference to the drawings.

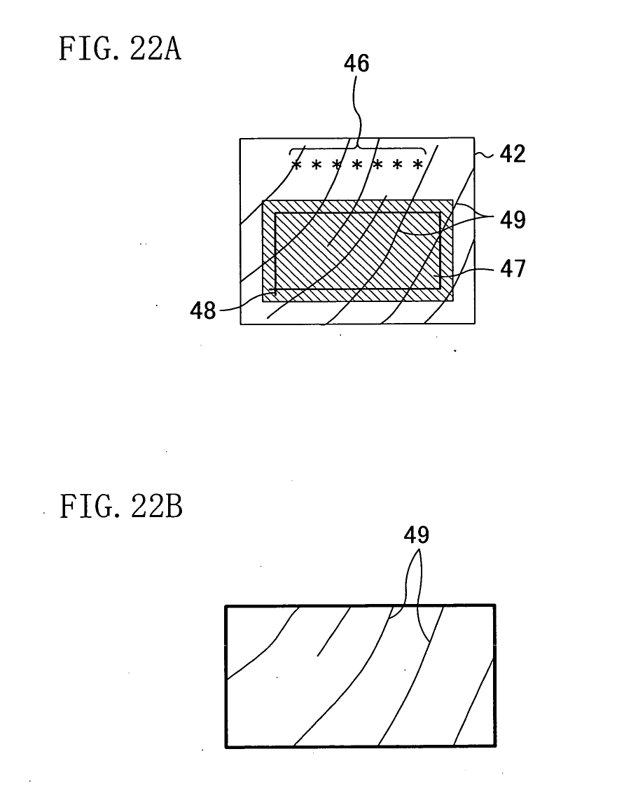

FIG. 22A shows the reverse face of a semiconductor integrated circuit chip used in the present embodiment, specifically, the reverse face of a semiconductor integrated circuit chip (a semiconductor integrated circuit chip mounted to a semiconductor package called a C-CSP) just the same as that shown in FIG. 21C in Embodiment 17. As shown in FIG. 22A, on the reverse face of the semiconductor integrated circuit chip 42, the imprint portion 46 for the product number and the like and the specific information reading region 47 for measuring a profile of the reverse face as the physically random specific information are provided. Further, in the specific information reading region 47 on the reverse face of the semiconductor integrated circuit chip 42, a starting point pattern 48 is provided for clearly indicating a measurement index of the profile of the reverse face. In FIG. 22A, the bold line indicates the reverse face profile observation region with the starting point pattern 48 as an index.

Back grinding to the reverse face of the semiconductor integrated circuit chip 42, which is performed before packaging the chip 42, generates flaws 49 all over the reverse face of the chip 42.

In the present embodiment, the flaws 49 out of the profiles of the reverse face of the semiconductor integrated circuit chip 42 is utilized particularly as the physically random specific information and a chip ID is set based on a measured value of an aspect of the flaws 49. Wherein, the flaws 49 can be detected easily by a microscope, a surface SEM or the like.

In the present embodiment, after the flaws 49 by back grinding the reverse face of the chip are observed by a microscope or a surface SEM, an image obtained by the observation is subjected to image processing to extract the aspect of the flaws 49 as shown in FIG. 22B, and then, the extracted aspect of the flaws 49 is used as a chip ID.

After the chip IDs are set for individual semiconductor integrated circuit chips as described above, the thus obtained chip IDs are stored in a database provided in a memory device of a computer, likewise the case of Embodiment 7. In this time, information on the chips (time when the diffusion process is performed for the semiconductor chip, a lot number, a wafer number, a chip address in the wafer, and the like) is stored into the database together with the chip IDs.

Thereafter, the semiconductor integrated circuit chips for which the chip IDs are set are shipped as products as usual.

When a semiconductor integrated circuit chip shipped as a product is judged as a market failure, the failed semiconductor integrated circuit chip is recovered to examine it to find a failure cause. Specifically, the aspect of the flaws (flaws generated in back grinding) in the reverse face of the chip, which serves as the physically random specific information, is measured again (re-evaluation using a surface SEM in the present embodiment). Subsequently, the aspect of the flaws thus measured and extracted is compared with the chip ID that has been stored in the database prior to the product shipment to acquire again the chip ID of the semiconductor integrated circuit chip. Whereby, information on the chip (time when the diffusion process is performed for the semiconductor chip, a lot number, a wafer number, a chip address in the wafer, and the like) can be acquired immediately based on the re-acquired chip ID, enabling speedy failure cause fining. Further, the chip ID is set using the physically random specific information, so that only the company that manufactured the chip can acquire again the various kinds of information on the chip including the chip ID.

As described above, in the present embodiment, an aspect of flaws generated in back grinding of the reverse face of a semiconductor integrated circuit chip is utilized as the specific information, so that the specific information becomes distinctive and physically random. In consequence, an unforgeable chip ID exhibiting a high-level information security function can be assigned to a semiconductor integrated circuit chip based on the specific information. In other words, an unforgeable semiconductor integrated circuit chip exhibiting a high-level information security function can be provided. Further, for immediately providing countermeasures for customers' benefits upon market failure of a semiconductor integrated circuit chip, the chip ID is re-extracted by measuring again the aspect of the flaws on the reverse face of the chip as the physically random specific information, enabling speedy failure cause finding. In addition, the chip ID of the present embodiment is set based on a topographic characteristic of a semiconductor integrated circuit chip, so that the chip ID of a semiconductor integrated circuit chip electrically inoperable due to market failure can be re-extracted independently from the electric circuit operation of the semiconductor integrated circuit chip. Thus, the effects of the present invention are significant.

In the present embodiment, it is needless to say that the method for extracting an aspect of flaws on the reverse face of a chip is not limited to the method by image processing. Further, any topographic characteristic other than the aspect of the flaws generated in back grinding may be utilized as the physically random specific information, of course.

What is claimed is:

1. A semiconductor package ID generating system, comprising:
a function of selecting a topographic characteristic to be utilized as specific information from at least one topographic characteristic that a semiconductor package has;
a function of measuring the selected topographic characteristic as the specific information; and
a function of generating an ID for identification for the semiconductor package based on the measured specific information.

2. A semiconductor integrated circuit chip ID generating system, comprising:
a function of selecting a topographic characteristic to be utilized as specific information from at least one topographic characteristic that a semiconductor integrated circuit chip has;
a function of measuring the selected topographic characteristic as the specific information; and
a function of generating an ID for identification for the semiconductor integrated circuit chip based on the measured specific information.

3. A semiconductor package ID recognizing system, comprising:
a function of selecting a topographic characteristic to be utilized as specific information from at least one topographic characteristic that a semiconductor package has;
a function of measuring the selected topographic characteristic as the specific information;
a function of generating an ID for identification for the semiconductor package based on the measured specific information;
a function of storing the generated ID for identification into a database; and
a function of acquiring again the ID for identification of the semiconductor package by re-measuring the selected topographic characteristic as the specific information and comparing the re-measured specific information with data stored in the database.

4. A semiconductor integrated circuit chip ID recognizing system, comprising:
a function of selecting a topographic characteristic to be utilized as specific information from at least one topographic characteristic that a semiconductor integrated circuit chip has;
a function of measuring the selected topographic characteristic as the specific information;
a function of generating an ID for identification for the semiconductor integrated circuit chip based on the measured specific information;
a function of storing the generated ID for identification into a database; and
a function of acquiring again the ID for identification of the semiconductor integrated circuit by re-measuring the selected topographic characteristic as the specific information and comparing the re-measured specific information with data stored in the database.

5. A semiconductor package ID recognition method, comprising the steps of:
selecting a topographic characteristic to be utilized as specific information from at least one topographic characteristic that a semiconductor package has;
measuring the selected topographic characteristic as the specific information;
generating an ID for identification for the semiconductor package based on the measured specific information;
storing the generated ID for identification into a database; and
acquiring again the ID for identification of the semiconductor package by re-measuring the selected topographic characteristic as the specific information and comparing the re-measured specific information with data stored in the database.

6. A semiconductor integrated circuit chip ID recognition method, comprising the steps of:
selecting a topographic characteristic to be utilized as specific information from at least one topographic characteristic that a semiconductor integrated circuit chip has;
measuring the selected topographic characteristic as the specific information;
generating an ID for identification for the semiconductor integrated circuit chip based on the measured specific information;
storing the generated ID for identification into a database; and
acquiring again the ID for identification of the semiconductor integrated circuit chip by re-measuring the selected topographic characteristic as the specific information and comparing the re-measured specific information with data stored in the database.

7. A semiconductor package, comprising:
a specific information reading region for measuring roughness of a surface of the semiconductor package as specific information for generating an ID for identification,
wherein a pattern serving as a starting point for measurement is provided within the specific information reading region.

8. The semiconductor package of claim 7,
wherein the surface of the semiconductor package in the specific information reading region is protected physically.

9. A semiconductor package ID recognition method, comprising the steps of:
measuring roughness of a surface of a semiconductor package as specific information;
generating an ID for identification for the semiconductor package based on the measured specific information and storing the thus generated ID for identification into a database; and
acquiring again the ID for identification of the semiconductor package by re-measuring the roughness as the specific information and comparing the re-measured specific information with data stored in the database.

10. A semiconductor package ID recognition method, comprising the steps of:
measuring a lead angle of a bonding wire provided in a semiconductor package as specific information;
generating an ID for identification for the semiconductor package based on the measured specific information and storing the thus generated ID for identification into a database; and
acquiring again the ID for identification of the semiconductor package by re-measuring the lead angle as the specific information and comparing the re-measured specific information with data stored in the database.

11. A semiconductor package ID recognition method, comprising the steps of:
measuring a contour of a bonding portion provided in a semiconductor package as specific information;
generating an ID for identification for the semiconductor package based on the measured specific information and storing the thus generated ID for identification into a database; and
acquiring again the ID for identification of the semiconductor package by re-measuring the contour of the bonding portion as the specific information and comparing the re-measured specific information with data stored in the database.

12. A semiconductor package ID recognition method, comprising the steps of:
measuring a shape of a bump provided in a semiconductor package as specific information;
generating an ID for identification for the semiconductor package based on the measured specific information and storing the thus generated ID for identification into a database; and
acquiring again the ID for identification of the semiconductor package by re-measuring the shape of the bump as the specific information and comparing the re-measured specific information with data stored in the database.

13. A semiconductor integrated circuit chip, comprising:
a specific information reading region provided on an obverse face, a side face, or a reverse face for measuring a topographic characteristic of a constitutional element of the semiconductor integrated circuit chip as specific information for generating an ID for identification.

14. The semiconductor integrated circuit chip of claim 13,
wherein the constitutional element is a metal film,
the topographic characteristic is an aspect of a grain boundary of the metal film, and
at least a part of the metal film is exposed in the specific information reading region.

15. The semiconductor integrated circuit chip of claim 13,
wherein the constitutional element is a wire,
the topographic characteristic is an edge outline of the wire, and
at least a part of the wire is exposed in the specific information reading region.

16. The semiconductor integrated circuit chip of claim 14,
wherein the specific information reading region is provided in a region other than a region where a bonding pad to which a bonding wire is connected is formed.

17. The semiconductor integrated circuit chip of claim 14,
wherein the metal film is made of copper, aluminum, tungsten, or an alloy thereof.

18. The semiconductor integrated circuit chip of claim 15,
wherein the specific information reading region is provided in a region other than a region where a bonding pad to which a bonding wire is connected is formed.

19. The semiconductor integrated circuit chip of claim 15,
wherein the wire is made of copper, aluminum, tungsten, or an alloy thereof.

20. A semiconductor integrated circuit chip ID recognition method, comprising:
a first step of measuring an aspect of grain boundaries of a metal film provided in a semiconductor integrated circuit chip as specific information;
a second step of generating an ID for identification for the semiconductor integrated circuit chip based on the measured specific information and storing the generated ID for identification into a database; and
a third step of acquiring again the ID for identification of the semiconductor integrated circuit chip by re-measuring the aspect of the grain boundaries as the specific information and comparing the re-measured specific information with data stored in the database.

21. The semiconductor integrated circuit chip ID recognition method of claim 20,
wherein the first step includes a step of extracting, after an image of the grain of the metal film is obtained, the aspect of the grain boundaries of the metal film by subjecting the image to image processing, and the second step includes a step of extracting a point that connects the grain boundaries with each other, which are extracted in the first step, and storing a position of the extracted point as the ID for identification into the database.

22. A semiconductor integrated circuit chip ID recognition method, comprising the steps of:
measuring an edge outline of a wire provided in a semiconductor integrated circuit chip as specific information;
generating an ID for identification for the semiconductor integrated circuit chip based on the measured specific information and storing the generated ID for identification into a database; and
acquiring again the ID for identification of the semiconductor integrated circuit chip by re-measuring the edge outline as the specific information and comparing the re-measured specific information with data stored in the database.

23. A semiconductor integrated circuit chip ID recognition method comprising the steps of:
measuring, as specific information, a profile of roughness or chapping generated in a side surface portion of a semiconductor integrated circuit chip in chip dicing;
generating an ID for identification for the semiconductor integrated circuit chip based on the measured specific information and storing the generated ID for identification into a database; and
acquiring again the ID for identification of the semiconductor integrated circuit chip by re-measuring the profile of the roughness or the chapping as the specific information and comparing the re-measured specific information with data stored in the database.

24. A semiconductor integrated circuit chip, comprising:
a specific information reading region on a reverse face thereof for measuring an aspect of the reverse face as specific information for generating an ID for identification,
wherein a pattern serving as a starting point for measurement is provided within the specific information reading region.

25. A semiconductor integrated circuit chip ID recognition method, comprising the steps of:
measuring an aspect of a reverse face of a semiconductor integrated circuit chip as specific information;
generating an ID for identification for the semiconductor integrated circuit chip based on the measured specific information and storing the generated ID for identification into a database; and
acquiring again the ID for identification of the semiconductor integrated circuit chip by re-measuring the aspect of the reverse face as the specific information and comparing the re-measured specific information with data stored in the database.
